(19) United States
(12) Patent Application Publication
(10) Pub. No.: US 2026/0173428 A1
(43) Pub. Date: Jun. 18, 2026

(54) Solution Processable Semiconductors

(71) Applicant: The Board of Trustees of the University of Illinois, Urbana, IL (US)

(72) Inventors: Qing Cao, Urbana, IL (US); Hsien-Nung Wang, Urbana, IL (US)

(21) Appl. No.: 19/423,885

(22) Filed: Dec. 17, 2025

Related U.S. Application Data
(60) Provisional application No. 63/735,743, filed on Dec. 18, 2024.

(51) Int. Cl. H10D 30/47; C23C 18/00; H10D 62/80

(52) U.S. Cl. CPC H10D 30/471; C23C 18/00; H10D 62/80

(57) ABSTRACT

Semiconductor materials composed of CuIn₃Se₅ or CuIn₅Se₈, electronic devices composed of such materials, and methods of fabrication thereof are provided that exhibit enhanced mobility or other electronic properties while also being formed via a low-thermal-budget process on a variety of amorphous or structured substrate materials. Material precursors (e.g., copper chalcogenides, indium selenides, other selenium-bearing materials) can be applied as a homogeneous, uniform layer on a substrate (e.g., via solution-phase processes) and then exposed to a low temperature heating step to decompose the precursors into the target semiconductor material. Devices composed of these materials can be easily and cost-effectively formed across large areas, facilitating fabrication of high-quality displays or other large-area components.

### CROSS-REFERENCE TO RELATED APPLICATION

The present application claims priority to U.S. Provisional Patent Application No. 63/735,743 filed Dec. 18, 2024, the entire contents of which are incorporated by reference into the present application.

### BACKGROUND

In semiconductor device fabrication, it is generally desirable to form semiconductor materials having high carrier mobilities in order to fabricate transistors or other devices that exhibit enhanced current capacities, switching speed, or other enhanced functional characteristics. In order to arrive at such material properties, many semiconductor compositions (e.g., doped monocrystalline silicon semiconductors) may require the use of complex, delicate, expensive, infrastructure-intensive, or otherwise difficult to accomplish fabrication techniques. Such techniques may exhibit undesirable thermal budgets, require a highly ordered substrate with limited size or other pre-processing prerequisites, or have other constraints. Such requirements can make it difficult to generate such high-quality semiconductor materials across large areas of a substrate, e.g., to generate a display or other large device or component that includes such semiconductor materials. This can be related to the enhanced difficulty of consistently applying temperatures, pressures, precursor densities or partial pressures, or other process variables across the entire surface of such a large area with less than a specified degree of variation (such variation leading, e.g., to undesirable levels of variability in the characteristics of the formed semiconductor material across the area of the formed device) and/or high manufacturing costs associated with reducing such variability to an acceptable level.

### SUMMARY

In a first aspect, an electronic system is provided that includes: a transistor, wherein the transistor comprises: a channel, wherein the channel comprises a layer of semiconductive material comprises one of CuIn₃Se₅ or CuIn₅Se₈.

In a second aspect, a semiconductive material is provided that includes one of CuIn₃Se₅ or CuIn₅Se₈

In a third aspect, a method is provided that includes: (i) depositing a layer of mixed precursor materials on a substrate, wherein the mixed precursor materials comprise a copper compound and an indium selenide; and (ii) heating the layer of mixed precursor materials to form a layer of semiconductive material on the substrate such that the layer of semiconductive material comprises one of CuIn₃Se₅ or CuIn₅Se₈.

These as well as other aspects, advantages, and alternatives will become apparent to those of ordinary skill in the art by reading the following detailed description with reference where appropriate to the accompanying drawings. Further, it should be understood that the description provided in this summary section and elsewhere in this document is intended to illustrate the claimed subject matter by way of example and not by way of limitation

### BRIEF DESCRIPTION OF THE FIGURES

The patent or application file contains at least one drawing executed in color. Copies of this patent or patent application publication with color drawings will be provided by the Office upon request and payment of the necessary fee.

FIG. 1 depicts experimental results, according to an example embodiment.

FIG. 2 depicts aspects of an experimental apparatus, according to an example embodiment.

FIG. 3 depicts experimental results, according to an example embodiment.

FIG. 4 depicts experimental results, according to an example embodiment.

FIG. 5 depicts experimental results, according to an example embodiment.

FIG. 6 depicts aspects of an experimental simulation, according to an example embodiment.

FIG. 7 depicts experimental results, according to an example embodiment.

FIG. 8 depicts experimental results, according to an example embodiment.

FIG. 9 depicts experimental results, according to an example embodiment.

FIG. 10 depicts aspects of an experimental simulation, according to an example embodiment.

FIG. 11 depicts experimental results, according to an example embodiment.

FIG. 12 depicts experimental results, according to an example embodiment.

FIG. 13 depicts aspects of an experimental simulation, according to an example embodiment.

FIG. 14 depicts experimental results, according to an example embodiment.

FIG. 15 depicts experimental results, according to an example embodiment.

FIG. 16 depicts aspects of an experimental simulation, according to an example embodiment.

FIG. 17 depicts experimental results, according to an example embodiment.

FIG. 18 depicts experimental results, according to an example embodiment.

FIG. 19 depicts experimental results, according to an example embodiment.

FIG. 20 depicts experimental results, according to an example embodiment.

FIG. 21 depicts experimental results, according to an example embodiment.

FIG. 22 depicts experimental results, according to an example embodiment.

FIG. 23 illustrates a flowchart of an example method.

FIG. 24 depicts experimental results, according to an example embodiment.

FIG. 25 depicts experimental results, according to an example embodiment.

FIG. 26 depicts experimental results, according to an example embodiment.

FIG. 27 depicts experimental results, according to an example embodiment.

FIG. 28 depicts experimental results, according to an example embodiment.

FIG. 29 illustrates a flowchart of an example method

### DETAILED DESCRIPTION

Examples of systems and methods are described herein. It should be understood that the words “exemplary,” “example,” and “illustrative,” are used herein to mean “serving as an example, instance, or illustration.” Any embodiment or feature described herein as “exemplary,” “example,” or “illustrative,” is not necessarily to be construed as preferred or advantageous over other embodiments or features. Further, the exemplary embodiments described herein are not meant to be limiting. It will be readily understood that certain aspects of the disclosed systems and methods can be arranged and combined in a wide variety of different configurations.

It should be understood that the below embodiments, and other embodiments described herein, are provided for explanatory purposes, and are not intended to be limiting.

### I. OVERVIEW

The current capacity, bandwidth, switching time, on resistance, or other functional characteristics of transistors, diodes, or other semiconductor devices are highly dependent upon the electronic of other material characteristics of the semiconductor materials (e.g., channel materials) from which the active elements of such devices are composed. These material characteristics (e.g., electron mobility, bandgap) are, in turn, highly dependent upon the specifics of the composition and fabrication of the semiconductor materials. For example, where the semiconductor material is a doped monocrystalline silicon material, acceptable material characteristics may depend on the material having very high purity and very few defects.

For many semiconductor materials, achieving such material characteristics requires highly controlled and specific fabrication processes, which can be expensive, difficult to achieve, high variability (leading to low yields), require significant infrastructure (e.g., large ovens, reaction chambers, or other systems to anneal, sputter, maintain a CVD or PVD precursor mix, or perform some other fabrication process), and/or significant constraints on the underlying substrate (e.g., that the substrate exhibit a consistent orientation, low-defect crystalline structure to act as the seed for the formation of a semiconductor overlayer). These difficulties can be enhanced when attempting to perform such fabrication processes over large areas (e.g., across the area of a large display). For example, the increased area/volume can lead to increased difficulties in applying a consistent temperature, pressure, CVD or other chemical precursor concentration(s)/partial pressure(s), sputtering particle rate, energy, or angle, or other process characteristics across the entire area, leading to undesirable levels of variability in material or device characteristics across the area/volume.

The semiconductor material compositions (and related fabrication methods) described herein overcome these limitations, exhibiting enhanced carrier mobility with good stability and uniformity and other desirable material properties while being fabricated via simple (e.g., solution phase), low-constraint (e.g., low thermal budget) processes across large areas of a substrate. These material compositions include films of CuIn₃Se₅ or CuIn₅Se₈ that exhibit a tetragonal crystal structure and enhanced material properties while being formed via advantageous processes, e.g., thermal decomposition at low temperature of precursors deposited via solution-phase processes. These enhanced material properties (e.g., high carrier mobility) may be related to the structure of defects within such materials, e.g., due to pairs of such defects interacting with each other, thereby ‘cancelling’ some or all of the negative effects thereof with respect to the electronic properties of the material (e.g., with respect to carrier-trapping and scattering by the paired defects).

As used herein, a “film,” “layer of semiconductive material,” “semiconductive material,” or similar element being described as being “composed of,” “comprised of,” “comprising,” or similar with respect to CuIn₃Se₅ or CuIn₅Se₈ is a film, material, or similar element whose composition is close enough to that of CuIn₃Se₅ or CuIn₅Se₈ (i.e., close enough to 1:3:5 or 1:5:8, respectively) that it exhibits the corresponding stannite or tetragonal crystal structure, respectively, (as a single crystal, or multiple crystals) throughout the film. The improved material properties (e.g., electron mobility) described herein can be obtained in such a film while varying the elemental composition of the film from the strict 1:3:5 or 1:5:8 of CuIn₃Se₅ or CuIn₅Se₈. For example, a ratio of Cu to In of between and between 2.4 and 3.6 for CuIn₃Se₅, or between 4 and 6 for CuIn₅Se₈, can obtain much of the material property benefits of the exact 1:3 or 1:5 ratios, respectively, with the ratio of Se being set such that the film forms with the desired stannite or tetragonal crystal structure.

Such films, having improved material properties, can be formed in a variety of ways. The properties of the CuIn₃Se₅ or CuIn₅Se₈ films described herein are such that they can be formed via low-cost, simple, resilient, and low thermal budget processes across large areas with high consistency with respect to film thickness and composition across the formed films. These processes can include depositing a layer of a homogeneous mixture of material precursors (e.g., Cu₂S or other copper chalcogenides, In₂Se₃ or other indium selenides, and elemental selenium) with the desired ratio of components and then exposing that layer to sufficient heat (e.g., a temperature greater than 350 degrees Celsius) to decompose the precursors into the desired CuIn₃Se₅ or CuIn₅Se₈ film. Such a precursor deposition process can be a solution-phase process, e.g., a process that includes depositing a uniform layer of a solution that includes the precursors dissolved and/or suspended in a solvent (e.g., hydrazine, a diamine, or a dithiol) onto a substrate and then evaporating the solvent therefrom (e.g., via a baking step). The solvent could include hydrazine, a combination of ethanedithiol and 1,2-ethylenediamine (e.g., at an approximately 1:10 ratio by volume), or some other solvent or combination of solvents. The precursor-bearing solution could be deposited via spin-coating, razor blading, stream casting, or some other method for depositing a uniform layer of a fluid onto a substrate.

These processes, and the low temperature of the decomposition step that leads to the generation of high quality semiconductor materials, allow transistors or other semiconductor devices having enhanced performance characteristics (e.g., high drive currents, high switching speed, large on/off ratios) to be formed across larger areas than are commercially feasible, or even practically possible, for alternative physiochemical processes that may rely on more delicate and exacting processes being applied uniformly across such large areas.

Layers of the CuIn₃Se₅ or CuIn₅Se₈ materials described herein can formed to have layer thicknesses between 10 nm and 20 nm in order to exhibit the enhanced electron mobility or other enhanced material properties described herein.

A variety of electronic devices can be formed from layers of the CuIn₃Se₅ or CuIn₅Se₈ materials described herein, e.g., with the layer of such materials forming the channel of a field effect transistor (FET, e.g., FinFET, JFET, MOSFET) of such an electronic device. The layers of CuIn₃Se₅ or CuIn₅Se₈ could be formed on a variety of monocrystalline, polycrystalline, amorphous, or otherwise configured layers, e.g., on an underlayer of HfO₂. Additional components/layers can then be formed, and optionally patterned, thereon, and the layer of CuIn₃Se₅ or CuIn₅Se₈ material can also be patterned (e.g., via photolithography) to separate the layer into electrically separated channels of respective transistors.

High-quality electrical connection of other elements of such an electronic device to a layer of the material(s) described herein can be accomplished using copper or chrome materials deposited onto a surface of the CuIn₃Se₅ or CuIn₅Se₈ material, with copper contacts exhibiting improved properties (e.g., reduced resistance) relative to chrome contacts. Where is it desired for the bulk of such a contact to be formed of a different material (e.g., aluminum, polycrystalline silicon, etc. that forms an interconnect layer of a device), a first layer of the contacts can be formed from copper (or chrome) and subsequent layer formed thereon that are compatible with copper (or chrome). In such examples, this compatible layer could be composed of the same material as the desired bulk material; alternatively, multiple layers could be deposited in turn, each relatively compatible with the prior and subsequent layers, to gradually form a structure that begins with copper (or chrome) and ends with the desired bulk material while still exhibiting good overall electronic and mechanical properties.

An electronic device containing a FET with a channel layer composed of the CuIn₃Se₅ or CuIn₅Se₈ materials described herein could be part of a complementary gate structure (e.g., as part of a CMOS device). In such examples, the first FET composed of the CuIn₃Se₅ or CuIn₅Se₈ channel materials could have stacked thereon a complementary transistor (e.g., a complementary FET of opposite polarity), with the two transistors sharing the same gate (e.g., a gate of Ti/Au between two HfO₂ or otherwise-composed insulating layers). The upper transistor could be composed of a natively p-type material and/or could be doped. For example, the channel of the upper transistor could be composed of p-doped carbon nanotubes, or a p-doped layer of CuIn₃Se₅ or CuIn₅Se₈.

Such transistors could be incorporated into such a device to provide a variety of functions. As noted above, the transistors could form part of logic gates, e.g., inverters, NAND gates, NOR gates, buffers, etc. Additionally or alternatively, such transistors could be used to drive high currents into light emitters (e.g., micro-LEDs), leading to high-performance, increased-brightness, or otherwise improved displays or other large-area arrays of driven elements.

### II. EXPERIMENTAL EMBODIMENTS

A variety of example embodiments of the subject matter of the present disclosure were created and experimentally evaluated. The specific processes, compositions, or other particulars of the below example embodiments are intended as non-limiting illustrative embodiments of the subject matter of the present disclosure. Modified, expanded, reduced, or otherwise altered versions of the below example embodiments are anticipated and within the scope of the present disclosure.

Solution-processable semiconductors hold promise for fabrication of cost-effective electronics at scale. However, prior methods suffer from low performance that is limited, e.g., by defects. Ordered defect compound semiconductor embodiments described and experimentally validated herein, including the ordered defect compound semiconductor CuIn₅Se₈, form regular defect complexes with defect-pair compensation. This allows these materials to achieve both high performance and solution processability. CuIn₅Se₈ transistors exhibit defect-tolerant, band-like transport supplying an output current above 35 microamperes per micrometer, with a large on/off ratio greater than 10⁶, a small subthreshold swing of 189±21 millivolts per decade, and a high field-effect mobility of 58±10 square centimeters per volt per second, with excellent uniformity and stability. This performance is superior to devices built on the less defective parent compound CuInSe₂, analogous binary compound In₂Se₃, and other solution-deposited semiconductors. The semiconductor materials described herein can be monolithically integrated with carbon nanotube transistors to form high-speed and low-voltage three-dimensional complementary logic circuits and with micro-light emitting diodes to realize high-resolution displays.

Solution-processable semiconductors facilitate scalable and cost-effective manufacturing of solid-state electronic devices. Nevertheless, the performance of transistors previously built on various semiconductors grown from solution, including silicon, metal oxides, metal chalcogenides, colloidal quantum dots, perovskites, one-dimensional (1D) or 2D nanomaterials, and organic semiconductors, has been severely limited by the prevalence of material structural defects formed from corresponding solution precursors in kinetically controlled deposition processes with limited thermal budget. These shortcomings have prevented the adoption of these materials in emerging applications. This is because such applications generally entail not only low-cost and high-throughput fabrication of electronics but also high performance, e.g., high-speed logic circuits for ubiquitous edge computing and high-resolution display backplanes driving miniaturized nitride light-emitting diodes (microLEDs).

Multiple approaches have been unsuccessfully explored previously to address charge-trapping and scattering defects in such solution-deposited semiconductors, such as avoiding defect formations through engineering the precursor chemistry or deposition conditions or confining carrier transport by forming complex layered superlattices and interfaces. The embodiments described herein include a counterintuitive strategy to achieve defect tolerance: more and heterogeneous types of defects are intentionally incorporated into the semiconductor material. These defects self-organize to form regular and electrically benign defect complexes, effectively cleaning up deep-level traps within the bandgap for improved performance. Several embodiments of such materials were experimentally verified using solution-deposited ternary copper-indium-selenium (Cu-In-Se) compound semiconductors as a model system. The experiments described herein demonstrate that thin films of the ordered defect compounds CuIn₃Se₅ and CuIn₅Se₈ can be deposited from the solution phase with precisely tunable stoichiometry and excellent compositional uniformity over large areas. Carrier transport in these materials with a high concentration of organized vacancies and anti-sites was found to be consistently superior, at least two to three times better in terms of effective mobility and subthreshold swing, than their less defective parent compound chalcopyrite CuInSe₂ or than the analogous pure binary In₂Se₃. In particular, CuIn₅Se₈ transistors achieved an average field-effect mobility of 58+10 cm² V⁻¹ s⁻¹ with the maximum in excess of 90 cm² V⁻¹ s⁻¹ and a high on-state current density above 35 A μm⁻¹ while maintaining a large on/off ratio greater than 10⁶ and a sharp subthreshold swing down to 135 mV decade⁻¹ with an average of 189±21 mV decade⁻¹. The performance of these devices, with excellent uniformity and stability, also matches or exceeds the best values reported for transistors built on other solution-processable semiconductors. CuIn₅Se₈ transistors were also monolithically integrated with their p-type counterparts built from solution-deposited semiconducting carbon nanotubes to form 3D high-speed complementary logic gates and ring oscillators with a short stage delay of 75 ns under a low supply voltage of 6 V. They were able to drive micrometer-sized micro-LEDs to a high current density above 200 A cm⁻², realizing high-resolution active matrix displays with pixels per inch (PPI) greater than 500.

### Experimental Results

### Solution Deposition and Characterizations of Cu—In—Se Defect Compound Semiconductors

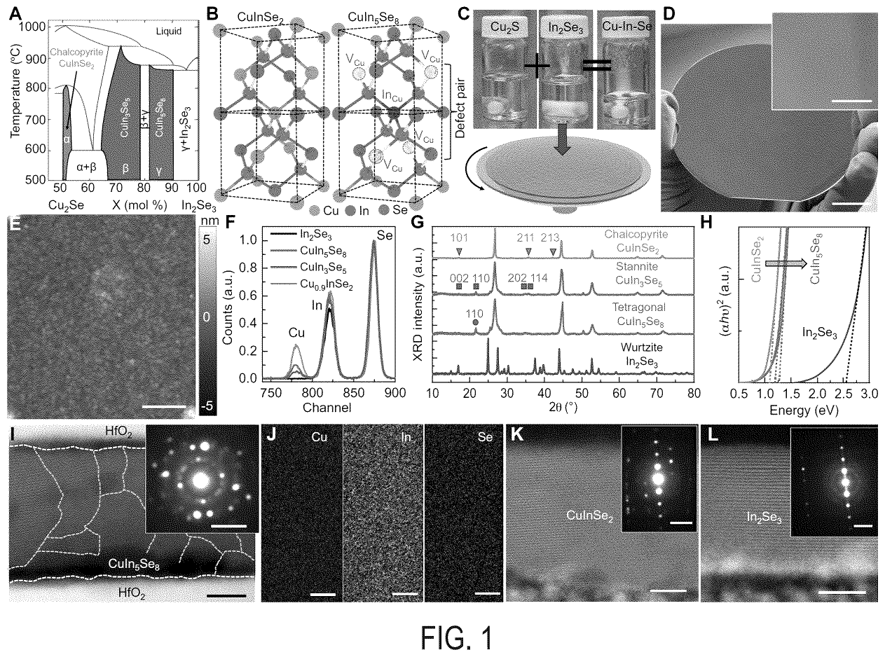

The ternary Cu—In—Se compounds along a composition tie-line connecting Cu₂Se and In₂Se₃ form a family of semiconductors (FIG. 1A). In addition to CuInSe₂ and In₂Se₃, which have drawn broad interest for their use in solar cells and transistors, there are two additional single-phase regions corresponding to indium-rich stoichiometries of CuIn₃Se₅ and CuIn₅Se₈. FIG. 1B depicts experimental and computational anti-sites (In²_{Cu}⁺) and copper vacancies (V⁻_{Cu}). These In²_{Cu}⁺ and V⁻_{Cu} defects were predicted and observed to pair up, forming defect clusters that are further arranged into ordered arrays or superlattices due to their dipole interactions. The formation of such ordered defect compounds has also been observed in other material systems such as Ba₃Nb₅O₁₅ and Cs₂SnI₆. Contrary to other semiconductors, where defects substantially degrade carrier transport and appear only randomly in very limited quantities, point defects in these ordered defect compounds such as CuIn₃Se₅ and CuIn₅Se₈ exist in a much higher concentration (>10%), sufficient to accommodate the stoichiometry change from CuInSe₂, but may be relatively benign to carrier transport after forming regular and electrically neutral V⁻_{Cu-}In²_{Cu}⁺−V⁻_{Cu} complexes, which push the deep In_{Cu} levels up closer to the conduction band edge, thus converting them from traps to shallow donors.

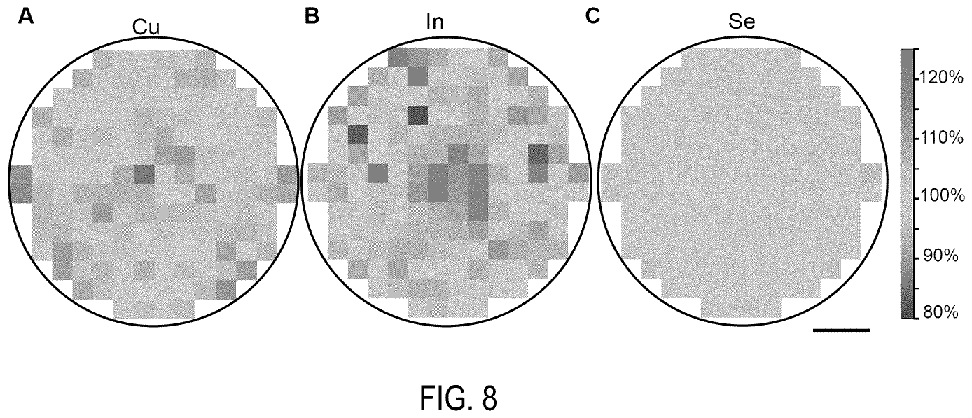

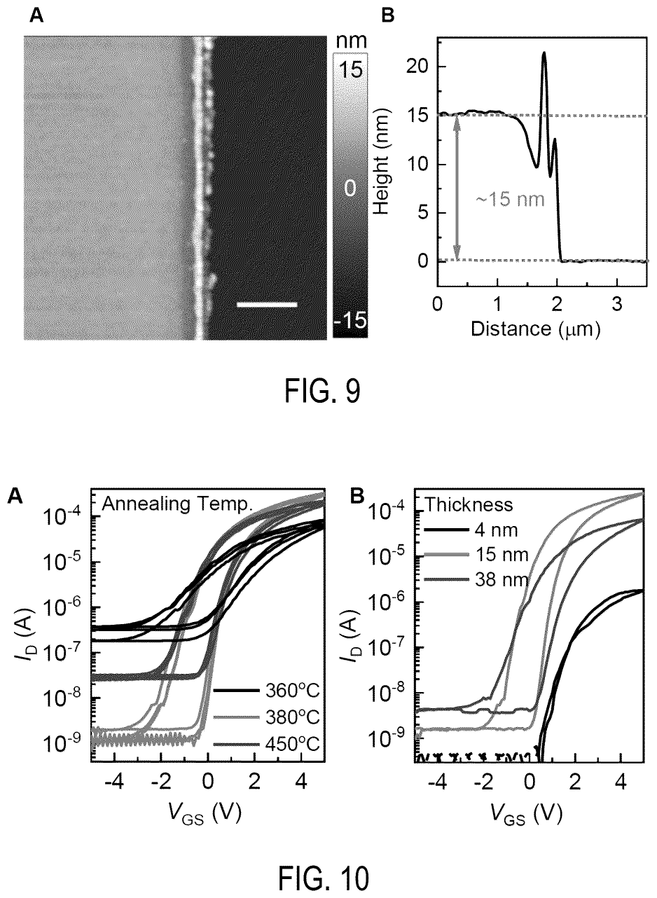

The formation of ultrathin Cu—In—Se films with precisely controlled and spatially uniform stoichiometries is challenging, for example, using vacuum deposition processes such as co-evaporation due to their complex ternary stoichiometry is challenging. Herein, an improved alternative method is described. Cu₂S and In₂Se₃ were first converted into molecular precursors of their hydrazinium salts, dissolved in hydrazine (FIG. 1C). Mixing these individual precursor solutions at a certain ratio formed a single solution that was homogeneous at a molecular level, which could then be deposited onto a solid substrate via scalable processes including spin casting. Because hydrazine species are only weakly coordinating with metal chalcogenides, low-temperature annealing in an inert oxygen-free atmosphere was able to effectively decompose the precursors into a mirror-like smooth Cu—In—Se film (FIG. 1D) with a uniform stoichiometry that was attainable over large areas, as verified by x-ray photoelectron spectroscopy (XPS) (FIG. 8). The thusly formed ˜15-nm-thick (FIG. 9) films exhibited a nanocrystalline structure with a low surface roughness (FIG. 1E), as measured by atomic force microscopy (AFM). The annealing temperature and channel semiconductor thickness affected the device performance. The optimum annealing temperature was about 380° C., which is above the decomposition temperature of the hydrazinium salts at ˜350° C. but safely below the typical thermal budget limit for monolithic integration (˜400° C.). The film thickness can be accurately specified such that the formed film is uniformly continuous and thus able to be fully depleted in the device off-state by the gate electric field (FIG. 10).

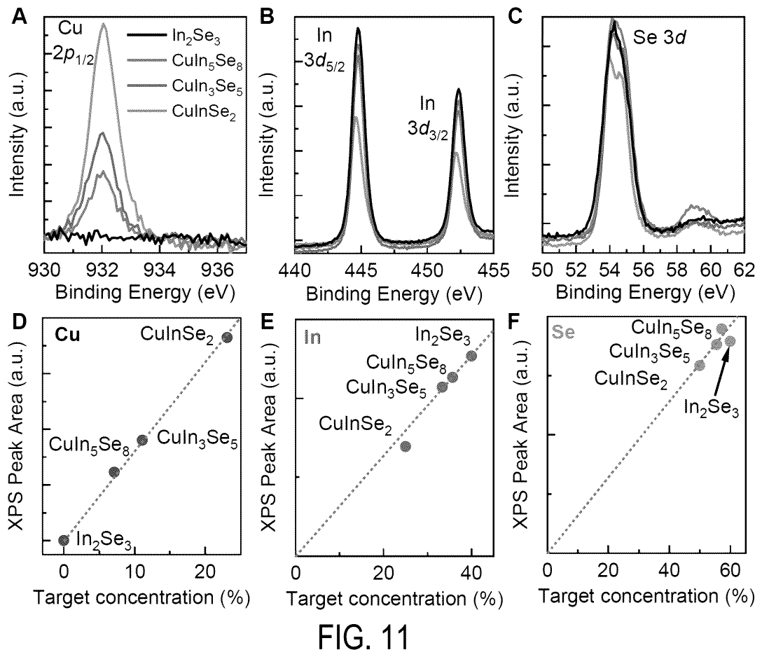

Deposition solution composition can be tuned by adjusting the mixing ratios between the Cu₂S and In₂Se₃ precursors, which precisely determine the stoichiometries of the formed solid thin films, resulting in a film whose composition is consistent (difference less than 8% for the Cu/In ratio) with the initially specified target composition. This was confirmed by Rutherford backscattering spectrometry (RBS) (FIG. 1F) and XPS (FIG. 11). The sulfur concentration was below the detection limit as most sulfur was lost during annealing due to its high vapor pressure. The CuInSe₂ was intentionally made slightly copper poor to avoid forming the metallic Cu₂Se phase; the V⁻_{Cu} acceptors can render the Cu_{0.9}InSe₂ p-doped. The x-ray diffraction (XRD) patterns confirmed the chalcopyrite structure of the prepared Cu_{0.9}InSe₂, while the tetragonal structure of the ordered defect compounds resulted in different extinction rules and thus the appearance of characteristic diffraction peaks (FIG. 1G), e.g., the strong (110) peak as predicted in simulation. Major diffraction peaks of Cu_{0.9}InSe₂, CuIn₃Se₅, and CuIn₅Se₈ were almost the same, suggesting a similar selenium backbone and similar lattice constant. The bandgap (E_{g}) extracted from these absorption spectra increased from 1.09 to 1.28 eV with the decrease in Cu/In ratio from Cu_{0.9}InSe₂ to CuIn₅Se₈ (FIG. 1H), in good agreement with bulk samples.

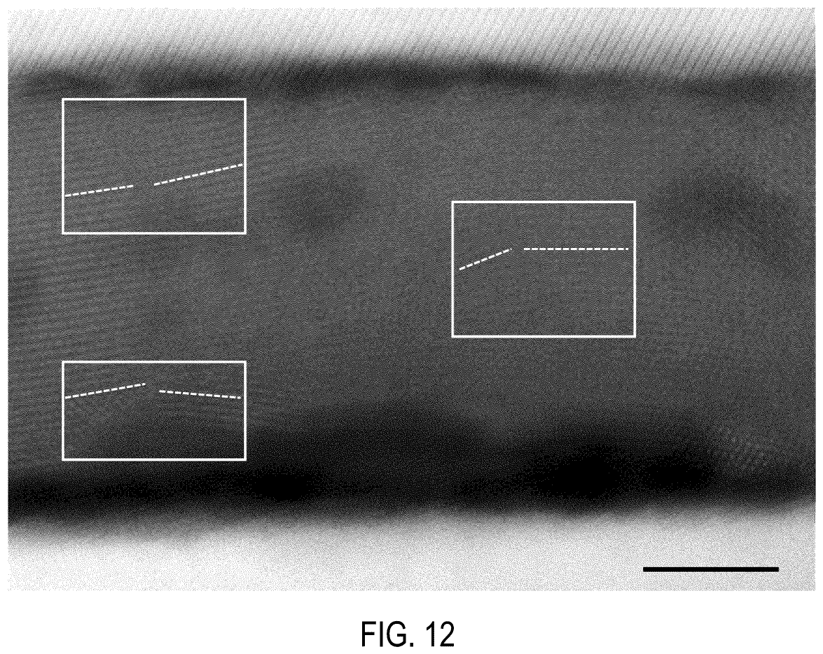

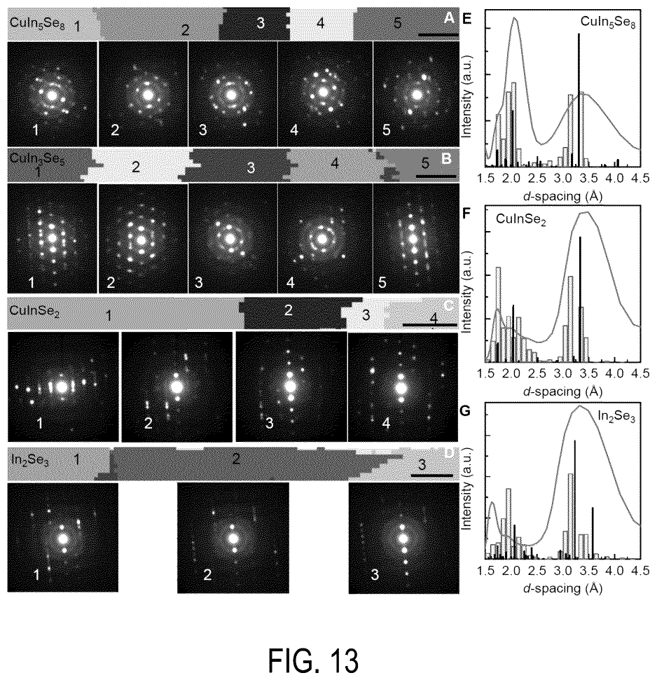

The nanocrystalline structure and ˜15 nm in thickness of the prepared Cu—In—Se thin films were further measured via high-resolution cross-sectional scanning transmission electron microscopy (STEM) (FIG. 11 and FIG. 12). Different grains and grain boundaries could be identified based on the change of atomic plane orientations. The associated energy-dispersive spectroscopy (EDS) mappings verified that the compositional uniformity of mixed precursor solutions on a molecular scale was translated to stoichiometric uniformity of the formed films on a sub-nanometer scale, without any noticeable composition variation from grain to grain (FIG. 1J). Compared to the parent compound Cu_{0.9}InSe₂ (FIG. 1K) and binary In₂Se₃ (FIG. 1L), the ordered defect compound CuIn₅Se₈ exhibited a smaller grain size and more structural imperfections, which were reflected in its more complex selected-area electron diffraction (SAED) patterns with powder-like rings (insets). This difference was more evident from scanning electron nano-diffraction imaging results obtained at a lower magnification (FIG. 13).

FIG. 1 depicts the deposition and characterization of Cu—In—Se thin films. (A) Cu₂Se—In₂Se₃ pseudo-binary phase diagram. The stable phases of CuInSe₂ with a chalcopyrite structure (a), CuIn₃Se₅ (β), and CuIn₅Se₈ (γ) with a tetragonal stannite structure are highlighted in green, blue, and red, respectively. (B) crystal structures of chalcopyrite CuInSe₂ (left frame) and tetragonal CuIn₅Se₈ (right frame). Cu, In, Se, In²_{Cu}⁺, and V⁻_{Cu} atomic sites are colored in yellow, blue, green, dark red, and gray with red dashed outline, respectively. (C) Schematic of the spin casting deposition of Cu—In—Se films with tunable composition. (D and E) Optical image [(d); scale bar, 2 cm; inset: zoom-in view with a scale bar of 5 mm] and AFM micrograph [(e); scale bar, 300 nm] of a CuIn₅Se₈ thin film deposited on a 4-inch diameter SiO₂/Si wafer substrate. (F and G) RBS (F) and XRd (G) spectra of prepared thin films with the measured stoichiometry of In₂Se₃ (black), Cu_{1.0}In_{3.0}Se₅ (blue), Cu_{1.05}In_{5.4}Se₈ (red), and Cu_{0.94}In_{1.1}Se₂ (green). Some of the characteristic XRd peaks are indexed. a.u., arbitrary units. (H) Tauc plot with the extrapolation of the linear region (dashed line) to determine their optical bandgaps. (I and J) high-resolution cross-sectional STEM micrograph [(i); inset: SAED pattern, scale bar, 5 nm⁻¹] and spatial elemental mapping [(J); Cu: blue, In: green, and Se: red] of deposited thin films of the ordered defect compound CuIn₅Se₈. Scale bars, 5 nm. Yellow dashed lines are visual guides to mark grain boundaries. (K and L) cross-sectional STEM images and SAED patterns (insets: scale bars, 5 nm⁻¹) of CuInSe₂ (K) and In₂Se₃ (l). Scale bars, 5 nm.

### Thin-Film Transistors Built on Solution-Deposited Cu—In—Se Defect Compound Semiconductors

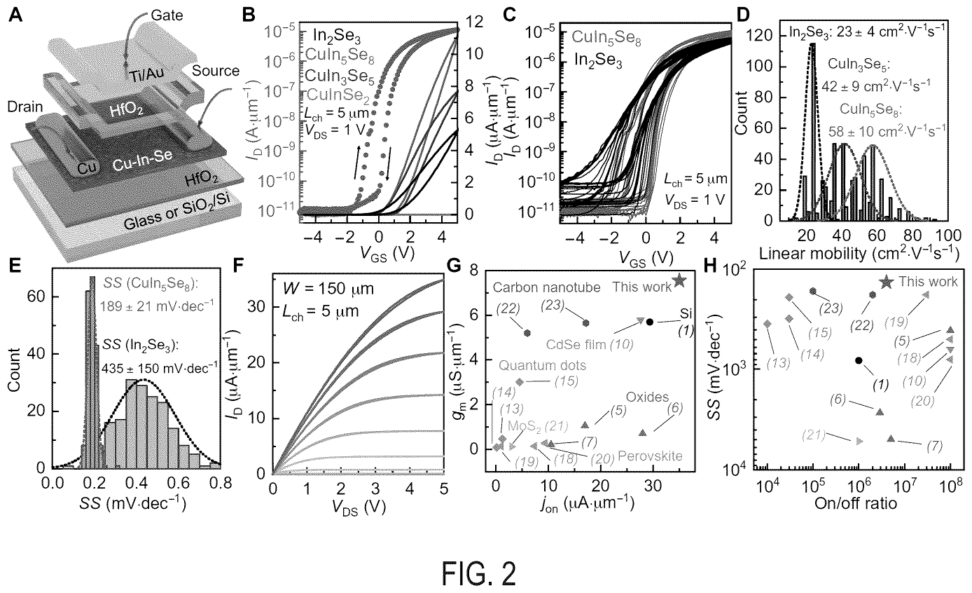

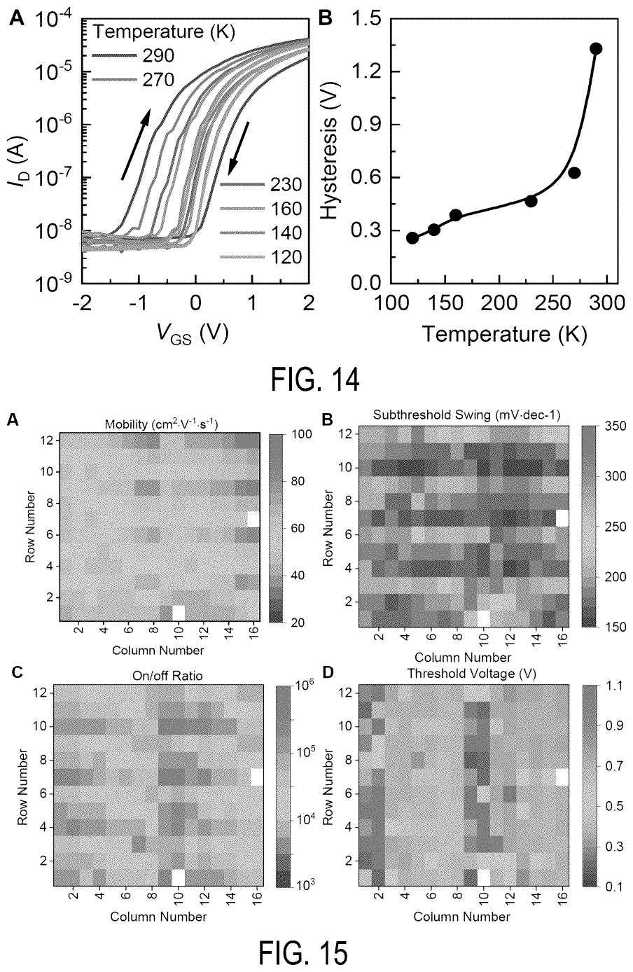

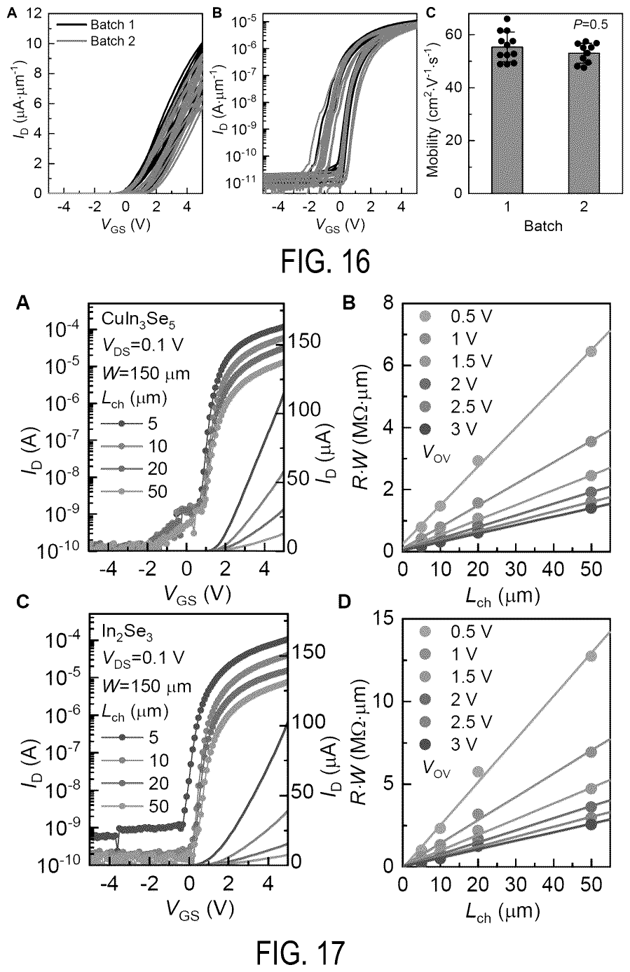

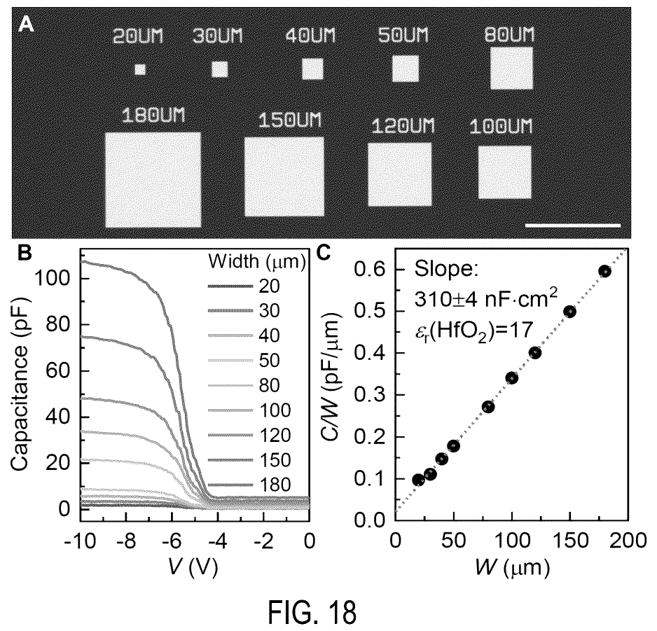

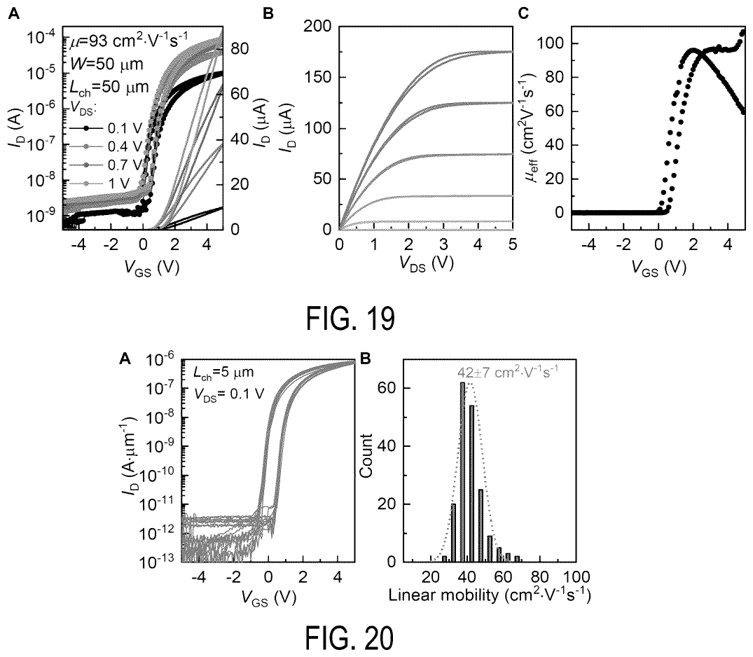

To evaluate their electrical properties, Cu—In—Se thin films, including Cu_{0.9}InSe₂, In₂Se₃, and ordered defect compounds CuIn₃Se₅ and CuIn₅Se₈, were solution deposited on 2×2 cm² SiO₂/Si or glass substrates and then incorporated as semiconductor channels in thin-film transistors adopting a top-gate and top-contact device structure, using copper electrodes as ohmic source-drain contacts and ˜50-nm HfO₂ as a high-κ (κ˜17) gate dielectric (FIG. 2A). Despite smaller grain size and higher structural defect density, the ordered defect compounds CuIn₃Se₅ and CuIn₅Se₈ exhibited substantially better device performance with defect-pair compensation (FIG. 2B), based on statistics from over 190 transistors each measured for stoichiometry (FIG. 2C). All devices regardless of the channel film stoichiometry showed a clockwise hysteresis, and the hysteresis decreased with the reduction in temperature (FIG. 14). These results indicate that the hysteresis is likely caused by traps at the gate oxide and chalcogenide semiconductor interface, leading to more pronounced hysteresis at a higher temperature due to thermal-assisted trapping and de-trapping of carriers. The nearly 100% device yield (190 of 192 for CuIn₅Se₈ transistors) and relatively small device-to-device (FIG. 15) and batch-to-batch (FIG. 16) variations indicate feasibility for large-scale and high-yield fabrication of integrated systems. The effective mobility of solution-deposited In₂Se₃ was 23±4 cm² V⁻¹ s⁻¹ (FIGS. 17 and 18), while the on current of Cu_{0.9}InSe₂ transistors was orders of magnitude smaller. The mobility was significantly enhanced to 42±9 cm² V⁻¹ s⁻¹ in CuIn₃Se₅, which is a superposition of CuInSe₂ and CuIn₅Se₈ phases, and further to 58±10 cm² V⁻¹ s⁻¹ in CuIn₅Se₈ (FIG. 2D; the P value for a two-sample unequal variance t test comparing against In₂Se₃ was 2.6×10⁻¹²³), with the maximum above 90 cm² V⁻¹ s⁻¹ (FIG. 19; similar mobility for both V_{GS} sweep directions), which indicates a low concentration of scattering sites and was among the highest ever reported for solution-deposited semiconductors (Table 1). It was only inferior to silicon, which requires 540° C. baking and excimer laser annealing or the highly toxic CdSe. Further increasing the indium content to an indium-to-copper atomic ratio of 7:1 lead to a comparatively lower average mobility of 42±7 cm² V⁻¹ s⁻¹ (FIG. 20), likely because the quantitative pair compensation between V⁻_{Cu} and In²_{Cu}⁺ was disrupted, but still substantially higher than that of In₂Se₃. In addition to mobility, improvement was also observed regarding subthreshold swing. CuIn₅Se₈ transistors exhibited a much sharper transition of 189±21 mV decade⁻¹, with the minimum down to 135 mV decade⁻¹, in comparison to 440±150 mV decade⁻¹ of In₂Se₃— based counterparts (FIG. 2E; P value=5.7×10⁻⁵⁵). The current-voltage characteristics of a CuIn₅Se₈ transistor showed an exceptionally high output current density of 35 μA μm⁻¹ under a low drive voltage of 5 V (FIG. 2F).

The performance of transistors built on the ordered defect compound CuIn₅Se₈ was benchmarked against the best values reported for devices using other semiconductors grown from solution (see Table 1; note that the comparison with nanotube transistors is intended for thin-film transistors with similar micrometer-scale channel length). Regarding on-state performance, the CuIn₅Se₈ transistors delivered the highest output current density and transconductance, which are the two most critical device parameters directly determining the capability to charge capacitors, drive external loads, and amplify signals (FIG. 2G). Regarding off-state performance, the CuIn₅Se₈ transistors achieved the smallest subthreshold swing together with a high on/off ratio above 10⁶, which indicates their low-power operation as an effective switch (FIG. 2H). The on/off ratio was limited by CuIn₅Se₈'s relatively small bandgap of 1.28 eV. These exceptional performance metrics were achieved because of the excellent carrier-transport properties of solution-deposited CuIn₅Se₈ as a defect-tolerant semiconductor, the formation of low-resistance ohmic contacts, and compatibility with standard microfabrication under ambient conditions.

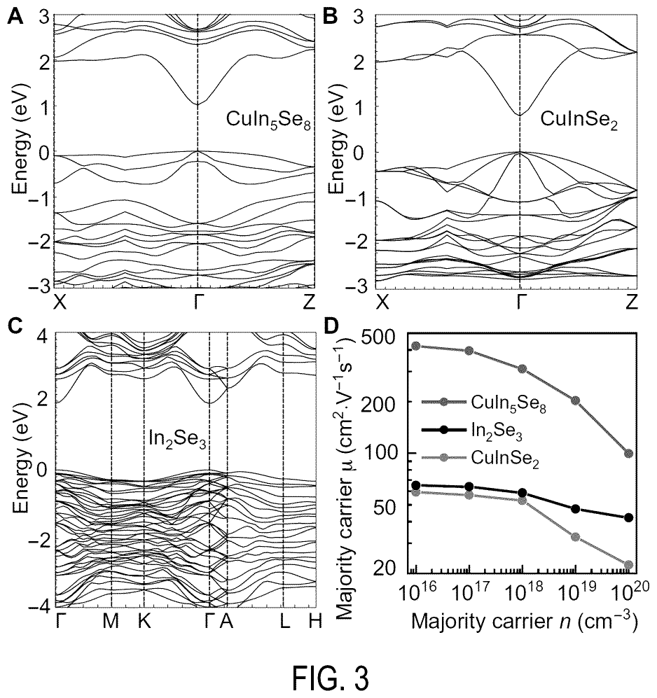

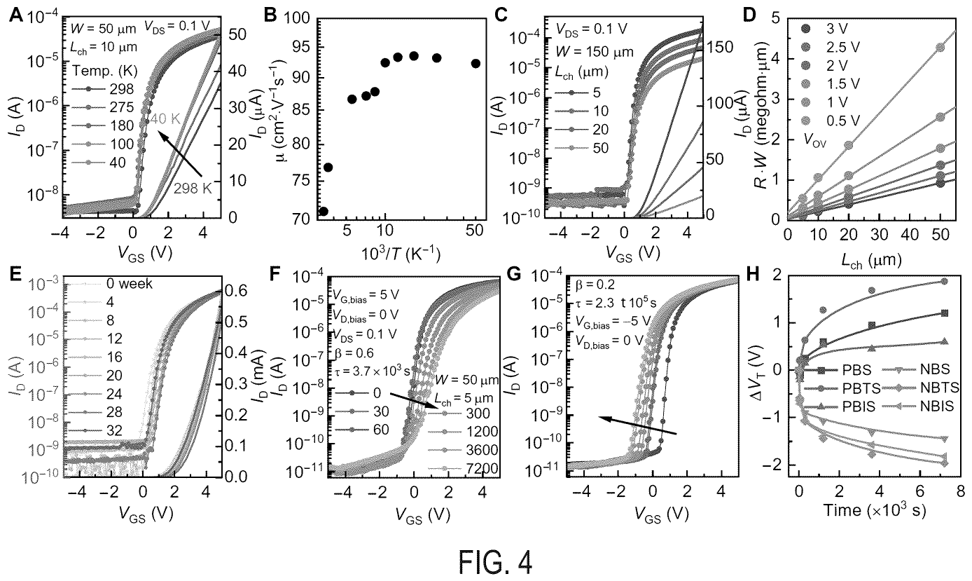

The band structure of the ordered defect compound CuIn₅Se₈ was calculated (FIG. 3A) and compared to CuInSe₂ (FIG. 3B) and In₂Se₃ (FIG. 3C) using density functional theory (DFT) with the Heyd-Scuseria-Ernzerhof (HSE) exchange-correlation functional, which gives more accurate electronic structures, especially bandgap, compared to the local density method. Compared to the parent compound chalcopyrite CuInSe₂, the bandgap of CuIn₅Se₈ was increased by ˜0.3 eV, caused by a reduced Se p-Cu d-orbital repulsion due to the presence of a large amount of Cu vacancies lowering the valence band minimum, much smaller than the bandgap of In₂Se₃. Both were consistent with experimental observations (FIG. 1H). On the basis of their ab initio band structures, the mobilities for the majority carrier transport in V⁻_{Cu} p-doped Cu-deficient CuInSe₂ and n-doped CuIn₅Se₈ and In₂Se₃ were calculated with the AMSET: ab initio scattering and transport using the Boltzmann transport equation, which considers both elastic and inelastic scattering mechanisms caused by ionized impurities, acoustic deformation potential, and polar optical phonons. CuIn₅Se₈ showed the best calculated mobility of 100 to 400 cm² V⁻¹ s⁻¹ (FIG. 3D), which is comparable to the maximum field-effect mobility (>90 cm² V⁻¹ s⁻¹) of the CuIn₅Se₈ transistors described herein and the Hall mobility (˜200 cm² V⁻¹ s⁻¹) of CuIn₅Se₈ single crystals. This improved carrier mobility in CuIn₅Se₈ may partially result from its ˜25% and ˜5 times lower simulated effective mass (0.12mₑ) than majority carriers in In₂Se₃ (0.15mₑ) and Cu-deficient CuInSe₂ (0.58mₑ), respectively, where mₑ represents the rest mass of electrons. Additionally, in CuIn₅Se₈, carriers are confined to the 2D Cu planes sandwiched between the regularly arranged In²_{Cu}⁺ and V⁻_{Cu} planes, further reducing scattering. In experiment, CuIn₅Se₈ transistors were measured under a variable temperature from 298 down to 40 K (FIG. 4A). The mobility decreased with the increase in temperature, suggesting band-like transport without being limited by thermionic emission across barriers (FIG. 4B). These results further confirm that the carrier transport through CuIn₅Se₈ crystals and grain boundaries is tolerant of the very-high-density vacancy and anti-site defects when they form regular, mutually compensating defect pairs.

FIG. 2 depicts transistors built on solution-deposited Cu—In—Se thin films. (A) Schematic illustration of a top-gated transistor consisting of a glass or SiO₂/Si wafer as the substrate, 40 nm of hfO₂ as the diffusion barrier, a spin-coated Cu—In—Se channel layer, patterned Cu source-drain electrodes, 50 nm of HfO₂ as the gate dielectric, and the gate metal stack of Ti/Au. (B) Representative transfer curves in a linear scale (right axis) of transistors with identical channel length (L_{ch}=5 μm) built on the ordered defect compounds CuIn₃Se₅ (blue) and CuIn₅Se₈ (red) as well as their parent compounds In₂Se₃ (black) and CuInSe₂ (magenta). Applied source-drain bias (V_{dS}) was 1 V. The left axis shows the modulation of channel width (W) normalized drain current (I_{d}) by the applied gate voltage (V_{GS}) for the CuIn₅Se₈ transistor in logarithmic scale. Devices showed a small hysteresis with arrows indicating the V_{GS} sweeping direction. (C) Collection of transfer characteristics of transistors with identical dimensions (W=150 μm and L_{ch}=5 μm) built on either In₂Se₃ (black) or CuIn₅Se₈ (red) channel. The applied V_{dS} was 1 V. (D and E) Histograms illustrating the distribution and average of effective mobility in the linear region (D) and subthreshold swing (SS) (E) of transistors built on In₂Se₃ (black), CuIn₃Se₅ (blue), or CuIn₅Se₈ (red). Dashed lines represent Gaussian fits to the data. (F) Output characteristics of a CuIn₅Se₈ transistor with L_{ch}=5 μm, measured with descending V_{GS} from 5 to 0 V at a step of 1 V from top to bottom. (G and H) Plots of channel width normalized transconductance (gₘ) versus current density (jₒₙ) (G) and SS versus I_{d} on/off ratio (H) to compare with the best transistors built on solution-deposited semiconductors previously reported in the literature. The present work (red star) showed the highest jₒₙ and gₘ and the lowest SS while exhibiting a large on/off ratio above 10⁶.

TABLE 1
Comparison of some of the best previously-fabricated thin-film
transistors built from solution-deposited semiconductors.

| | Mobility | Iₒₙ | Maximum gₘ | On/off | SS | L_{ch} | Gate | tₒₓ |
|---|---|---|---|---|---|---|---|---|
| Materials | (cm²V¹s⁻¹) | (μA μm⁻¹) | (μS μm⁻¹) | ratio | (mV decade⁻¹) | (μm) | oxide | (nm) |
| CuIn₅Se₈ | 58 ± 10; | 35 | 7.6 | 4 × 10⁶ | 135 | 5 | HfO₂ | 48 |
| | up to 93 | | | | | | | |
| Silicon | 74-108 | 29.4 | 5.7 | 10⁶ | 820 | 10 | SiO₂ | 120 |
| IGZO | 8.8 ± 1 | 4.13 | 0.9 | 10⁸ | 169 | 10 | Al₂O₃ | 35 |
| IZO | 11.4 ± 0.4 | 0.37 | 0.024 | 10⁸ | 600 | 300 | SiO₂ | 100 |
| In₂O₃ | 39.5 | 0.11 | 0.12 | 10⁴ | 90 | 100 | Al₂O₃ | 38 |
| ITZO/IGZO | 38 ± 5 | 17 | 1.04 | 10⁸ | 410 | 50 | Al₂O₃ | 50 |
| In₂O₃/ZnO | 50 | 28 | 0.7 | 2.9 × 10⁶ | 2710 | 50 | SiO₂ | 100 |
| In₂O₃/ZnO | 30 | 10.5 | 0.2 | 5 × 10⁶ | 5000 | 100 | SiO₂ | 400 |
| IGZO | 18 | 0.32 | 0.5 | 4 × 10⁴ | 150 | 10 | Al₂O₃ | 20 |
| SnS₂₋ₓSeₓ | 13.3 | 2.75 | 0.1 | 10⁶ | ~8000 | 14 | SiO₂ | 210 |
| CdSe film | 214 ± 33 | 27.6 | 5.8 | 10⁸ | 625 | 5 | Al₂O₃ | 56 |
| CdSe particles | 10.1 ± 0.3 | 1.25 | 0.46 | 10⁴ | 350 | 10 | Al₂O₃ | 20 |
| CdSe particles | 21.7 ± 4.5 | 0.13 | 0.078 | 3 × 10⁴ | 310 | 30 | Al₂O₃ | 80 |
| CdSe particles | 210 | 4.5 | 3 | 3 × 10⁴ | 190 | 30 | ZrO₂ | 10 |
| CuInSe₂ particles | 0.70 ± 0.05 | 0.02 | 0.0014 | 10⁴ | 5000 | 100 | SiO₂ | 300 |
| CuInSe₂ particles | 9.6 | 1.7 | 0.12 | 1.7 × 10⁴ | 800 | 100 | Al₂O₃ | 200 |
| CsSnI₃ + PbI₂ | 55 | 7.4 | 0.14 | 10⁸ | 500 | 150 | SiO₂ | 100 |
| MASni₃ | 19.6 ± 1.2 | 1.04 | 0.13 | 3 × 10⁷ | 180 | 150 | hfO₂ | 40 |
| CsFAPeA | 67.6 ± 3.6 | 9.4 | 0.27 | 10⁸ | 500 | 200 | SiO₂ | 100 |
| MoS₂ | 7-11 | 3 | 0.11 | 10⁶ | 5200 | 40 | SiO₂ | 90 |
| Carbon nanotube | 55 ± 9 | 17.2 | 5.65 | 2 × 10⁶ | 180 | 2 | Al₂O₃/HfO₂ | 40/10 |
| Carbon nanotube | 23 ± 2 | 6 | 5.2 | 10⁵ | 165 | 2 | Al₂O₃/SiO₂ | 25/3 |

IZO, indium-zinc oxide; ITZO, indium-tin-zinc oxide; IGZO, indium-gallium-zinc oxide; MASni3, methylammonium tin iodide; csFAPeA, cesium-formamidinium-phenethylammonium.

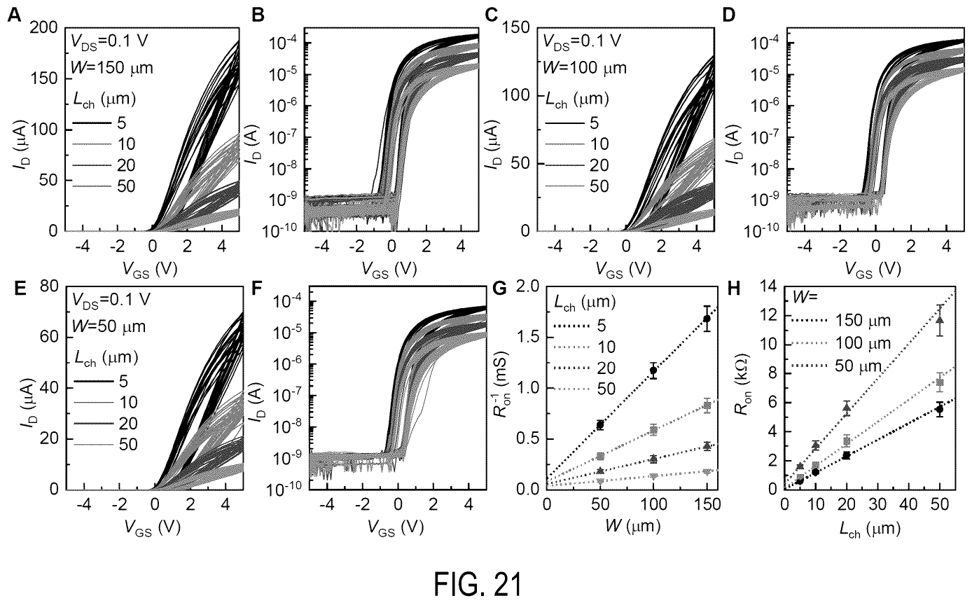

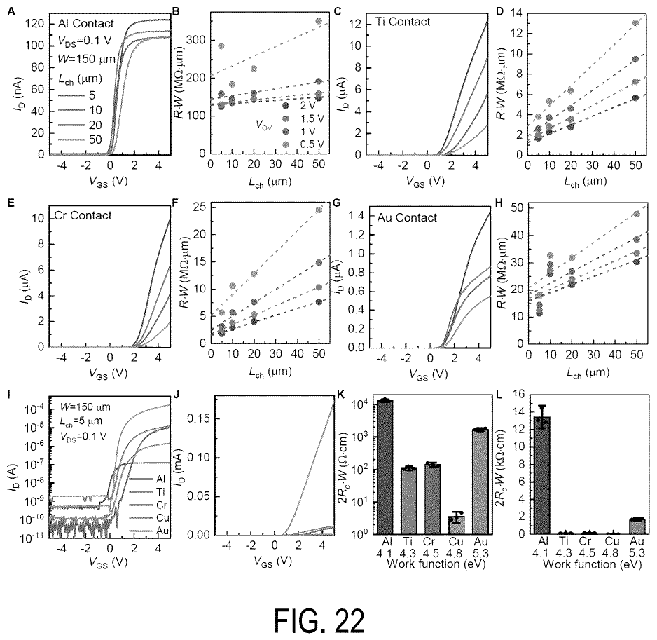

Scaling behaviors of CuIn₅Se₈ transistors were characterized. On-state conductance of transistors with the same geometries exhibited small variation (relative SD less than 12%), with their averages scaling linearly with channel width and its reciprocal (that is, resistance) proportionally with the channel length (FIG. 21). The parasitic contact resistance was extracted from linear regime transfer curves of four neighboring transistors with their channel lengths varying from 5 to 50 μm (FIG. 4C). The width normalized total resistance, as a series combination of channel and contact resistance, decreased linearly with the reduction in channel length, and the contact resistance can be determined from the y-axis intercept of linear fits to the data. These effects were negligible across the ranges of channel length and gate voltage (FIG. 4D), allowing for scaling toward high output current density and transconductance. The low contact resistance of ˜3 ohm cm was realized through the use of copper contacts, which may form a conductive copper-rich selenide interfacial layer with the channels (FIG. 22).

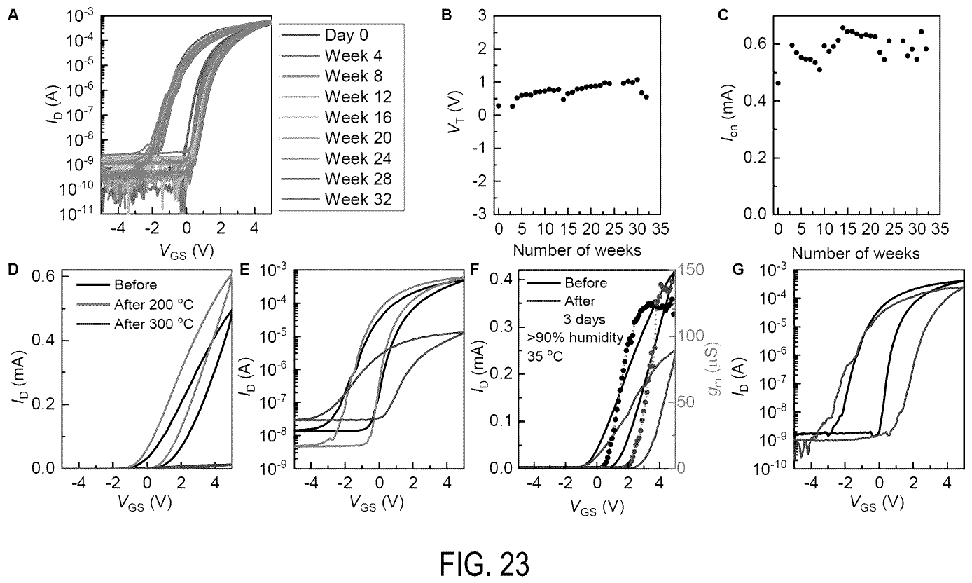

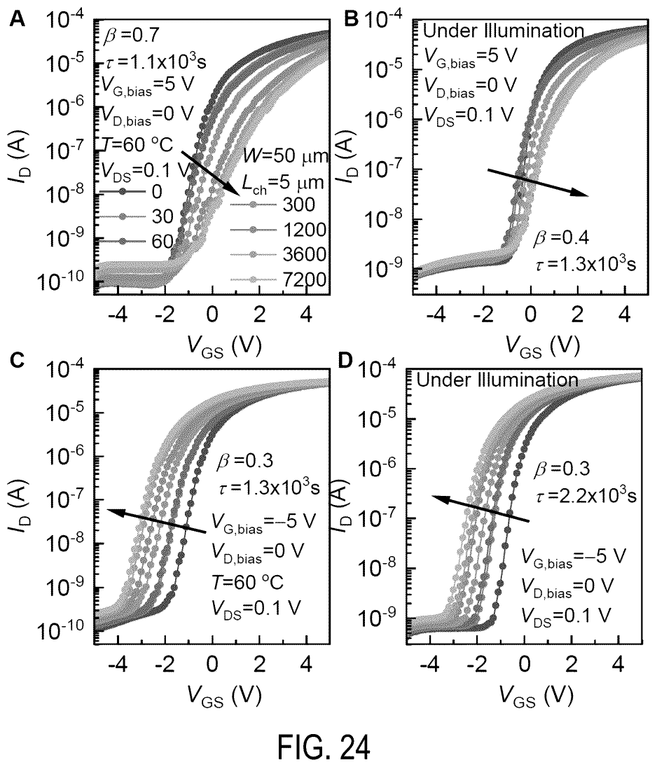

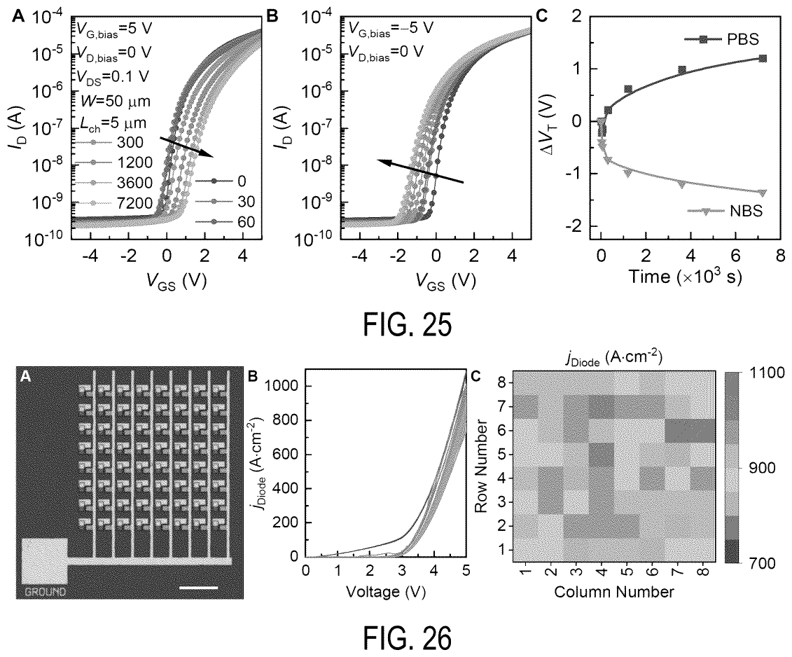

CuIn₅Se₈ thin films demonstrated good environmental stability, enduring exposure to air, solvents, and baking during the fabrication flow, resulting in advanced device structures with scaled dimensions and integrated high-x dielectrics for high levels of performance. There was little change in device characteristics after being stored in air at room temperature with a typical humidity level of 30 to 50% for ˜8 months (FIG. 4E and FIG. 23; showing only a small drift of V_{T} and Iₒₙ). The device was stable when annealed in air at 200° C.; meanwhile, when stored in air with a high humidity of >90% at an elevated temperature of 35° C., device peak transconductance was preserved, though a more substantial shift of V_{T} together with increased hysteresis was observed, which may have been caused by diffusion of water molecules across the gate oxide to accumulate at the interface with the CuIn₅Se₈ channel, acting as interfacial traps. Overall, the stability of CuIn₅Se₈ transistors was substantially better than those built on solution-deposited metal chalcogenides, quantum dots, perovskites, and organic semiconductors, suggesting the absence of activated structural defects with high chemical reactivity in the semiconductor channel. Stress tests were also conducted, including positive gate-bias stress (PBS) (FIG. 4F), negative gate-bias stress (NBS) (FIG. 4G), positive-bias temperature stress (PBTS), negative-bias temperature stress (NBTS), positive-bias illumination stress (PBIS), and negative-bias illumination stress (NBIS) tests (FIG. 24). The threshold voltage shift ΔV_{T} as a function of stress time t was fitted to a stretched exponential model

$$Δ {V}_{T} ( t ) = [ {V}_{T} ( ∞ ) - {V}_{T} ( 0 ) ] \times [ 1 - {exp ( - t / τ )}^{β} ]$$

where V_{T}(∞)−V_{T}(0) is the ΔV_{T} from the initial to equilibrium, T is the characteristic time constant associated with charge trapping, and β is the stretching parameter which indicates the time required for V_{T} to reach equilibrium (FIG. 4H). The ΔV_{T} was less than 1.4 V in PBS and NBS after a gate bias stress time of 2 hours but increased when subjected to thermal stress, with β in the range of 0.3 to 0.7. The ΔV_{T} under PBS and NBS was similar to that of In₂Se₃ transistors (FIG. 25), showing that the device reliability is likely not limited by the high concentration of point defects in the ordered defect compound but rather by traps at interfaces or impurities, although there could also be contributions from the dynamic creation of defects by breaking weak bonds within Cu—In—Se compound semiconductors. This bias-stress reliability was also comparable to the best transistors built on other solution-deposited semiconductors and typical thin-film transistors built on vacuum-deposited metal oxides, MoS₂, and amorphous silicon (Table 2). To improve the operational stability, the semiconductor-dielectric interface can be improved using improved material deposition and etching conditions, reducing extra impurities within the device gate stack, and/or the use of circuit-level compensations.

FIG. 3 depicts calculated electronic band structures and carrier transport properties of Cu—In—Se compounds. (A to C) Band structures of CuIn₅Se₈ (A), CuInSe₂ (B), and In₂Se₃ (c) from DFT calculations. (D) Room temperature mobility as a function of majority carrier concentration n, which is approximately the ionized dopant impurity concentration, of CuIn₅Se₈ (red), CuInSe₂ (magenta), and In₂Se₃ (black).

Monolithic 3D Integration of CuIn₅Se₈ Transistors with Heterogeneous Devices

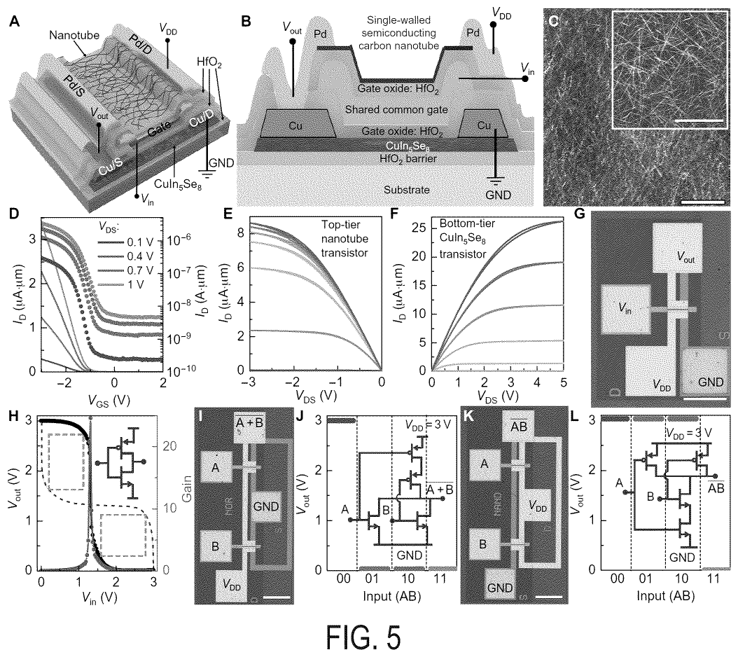

The ordered defect compound CuIn₅Se₈ exhibits low-temperature solution processability without compromising carrier-transport properties or material stability, facilitating cost-effective and scalable fabrication of uniform, high-performance planar transistors. An advantage of these CuIn₅Se₈ transistors, in addition to their excellent switching characteristics and large output current density, is that they can be monolithically integrated under a low thermal budget with other electronic and optoelectronic devices in a 3D architecture to achieve better performance, higher integration density, and enhanced functionality. By integrating a bottom-gated p-channel nanotube transistor vertically on top of a top-gated n-channel CuIn₅Se₈ transistor, a 3D complementary inverter can be realized (FIG. 5A), which exhibits negligible steady-state power dissipation as a significant advantage over inverters built on unipolar metal-oxide transistors. Compared to inverters built on complementary nanotube transistors, the CuIn₅Se₈ transistor described herein offers substantially higher performance than n-channel nanotube transistors formed by electrostatic doping, leading to enhanced inverter circuit switching speed or other benefits. Additionally, with the same gate electrode shared by transistors in two different levels, such a configuration can simplify the fabrication flow by implicating a reduced number of mask levels and improving the integration density with 3D stacking (FIG. 5B). The top-tier transistor was built on solution-deposited semiconducting carbon nanotube random networks (FIG. 5C), exhibiting p-channel transistor operations (FIGS. 5, D and E). The addition of the top-tier transistors did not affect the operation of the bottom-tier n-channel CuIn₅Se₈ transistors (FIG. 5F). The completed inverters (optical micrograph shown in FIG. 5G) exhibited well-defined static transfer characteristics at a low supply voltage V_{DD} of 3 V (FIG. 5H). The voltage gain was ˜25 with full swing to V_{DD}, better than previous nanotube-IGZO (indium-gallium-zinc oxide) hybrid complementary inverters operated under similar V_{DD}. A large inverter noise margin of 0.95 V (63% of V_{DD}/2), shown as dashed boxes in the “eye” pattern, was achieved and can be further improved by adjusting the device dimensions to compensate for the comparatively lower performance of nanotube transistors. Connecting multiple inverters together forms NOR (not or) and NAND (not and) gates (FIG. 5, I to L). These both exhibited reliable Boolean functionalities with rail-to-rail switching. The voltage inputs to A and B were V_{DD}=3 V or ground, representing logic “1” and “0,” respectively. The outputs ranged from 2.99 to 3 V as logic 1 and from 0 to 0.03 V as logic 0.

FIG. 4 depicts electrical characteristics of CuIn₅Se₈ transistors. (A) transfer characteristics of CuIn₅Se₈ transistors with W=50 μm and L_{ch}=10 μm measured at varying temperatures from 298 K down to 40 K in both logarithmic scale (left axis, dots) and linear scale (right axis, lines). The applied V_{dS} was 0.1 V. (B) temperature dependence of the extracted field-effect mobility. (C) transfer characteristics of CuIn₅Se₈ transistors with W=150 μm and L_{ch}=5 μm (black), 10 μm (red), 20 μm (blue), and 50 μm (green) in both logarithmic scale (left axis, dots) and linear scale (right axis, lines). The applied V_{dS} was 0.1 V. (D) Width normalized channel resistance as a function of L_{ch} at varying gate over drive (V_{Ov}=V_{GS}−Vₜ) from 0.5 to 3 V at a step of 0.5 V from top to bottom. (E) transfer characteristics of the same CuIn₅Se₈ transistor measured after the chip was stored in air up to 32 weeks, showing no performance degradation. (F and G) PBS (F) and NBS (G) data of CuIn₅Se₈ transistors measured during 2-hour bias-stress conditions with a positive or negative gate bias of V_{G,bias}=±5 V and drain bias of V_{d,bias}=0 V. (H) corresponding change in Vₜ (that is, ΔVₜ) as a function of stress time for various stability tests.

TABLE 2
Bias-stress stability of thin-film transistors built on both
solution and vacuum-deposited semiconductors. PMMA, polymethyl
methacrylate; PvP, poly(4-vinylphenol); n.r., not reported.

| | | | | | |
|---|---|---|---|---|---|
| | Mobility | | Stress field | V_{GS}_{^{Stress}} | PBS ΔV_{T}_{₄} |
| Materials | (cm²V⁻¹s⁻¹) | Dielectric | (MV cm⁻¹) | (V) | (V) @ ~10⁴s |

Thin- film transistors built on solution- deposited semiconductors

| | | | | | |
|---|---|---|---|---|---|
| CuIn₅Se₈ | 58 ± 10; up to 93 | HfO₂ | 1 | 5 | 1.2 |
| IGZO | 8.8 ± 1 | Al₂O₃ | 1.4 | 5 | 1.1 |
| IZO | 11.4 ± 0.4 | SiO₂ | ~1 | ~10 | 4 |
| In₂O₃/ZnO | 50 | SiO₂ | 3 | 30 | 2.25 |
| CdSe film | 214 ± 33 | SiO₂ | 1 | 5 | 0.46 |
| CsSnI₃ + PbI₂ | 55 | SiO₂ | 4 | 40 | 5.2 |
| CsPFPeA | 67.6 ± 3.6 | SiO₂ | 4 | 40 | 3.5 |
| PbS particles | 1 × 10⁻³ − 8 × 10⁻³ | PMMA | ~0.8 | 40 | ~12 |
| Carbon nanotube | 12.03 | PvP | 0.14 | 10 | 2 (with passivation) |
| Carbon nanotube | 10.2 ± 0.2 | SiO₂ | 2 | 10 | 3.6-4.4 |

Thin- film transistors built on vacuum- deposited semiconductors

| | | | | | |
|---|---|---|---|---|---|
| IGZO | 15 | SiO₂ | 1.5 | 30 | ~6 |
| MoS₂ | 5-14 | SiO₂ | 1.2 | 3 | 1 |
| Amorphous Si | n.r. | SiNₓ | ~1 | 35 | ~3 |
| Amorphous Si | 0.9 | SiNₓ | 0.67 | 20 | 4.2 |

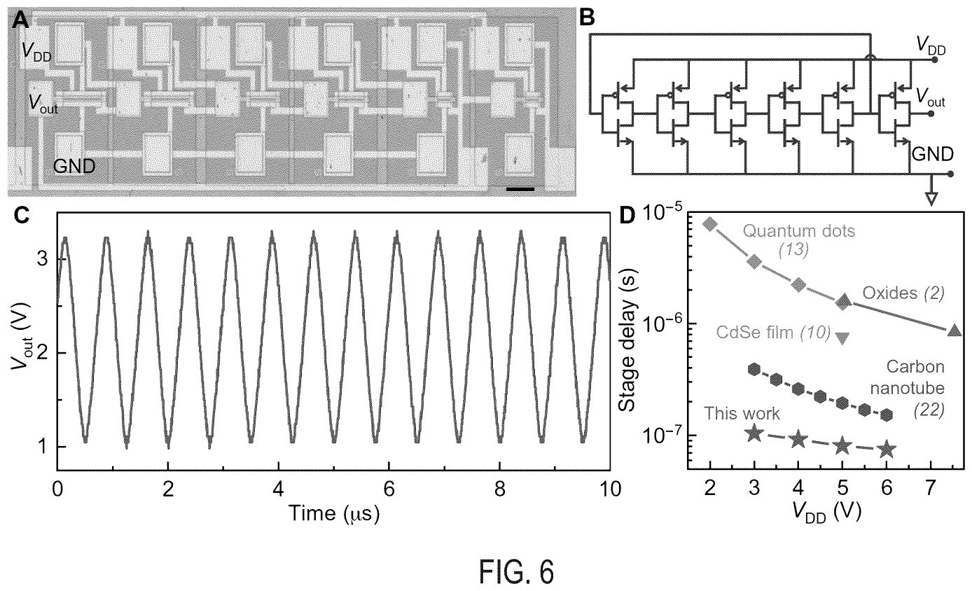

Five-stage ring oscillators were also fabricated and experimentally evaluated, with an additional inverter stage used as an output buffer (FIGS. 6, A and B). Of the 16 ring oscillators fabricated, 10 showed reliable signal propagation through logic switching in all six inverters. At a low supply voltage of 6 V, there was a 2.3-V output swing oscillating up to 1.33 MHz (FIG. 6C). This corresponded to a stage delay of 75 ns, which may have been limited by the large device channel length of 5 μm and the parasitic capacitance that resulted from the large overlap distance of 5 μm between the gate and each source-drain electrode. This still substantially outperforms ring oscillators built on other solution-deposited semiconductors under the same drive voltage for high-speed, low-voltage electronics (FIG. 6D), showcasing the performance advantage of CuIn₅Se₈ transistors with higher mobility and thus channel transconductance.

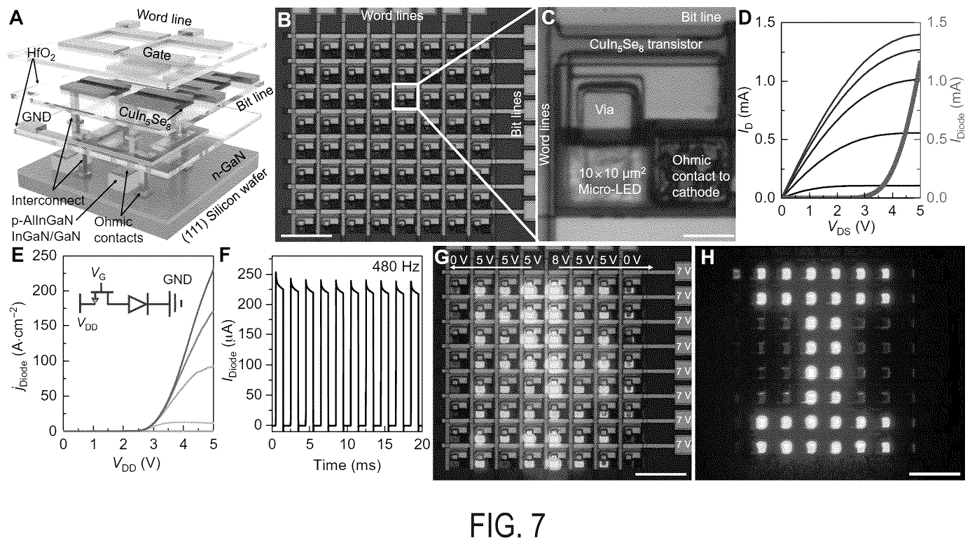

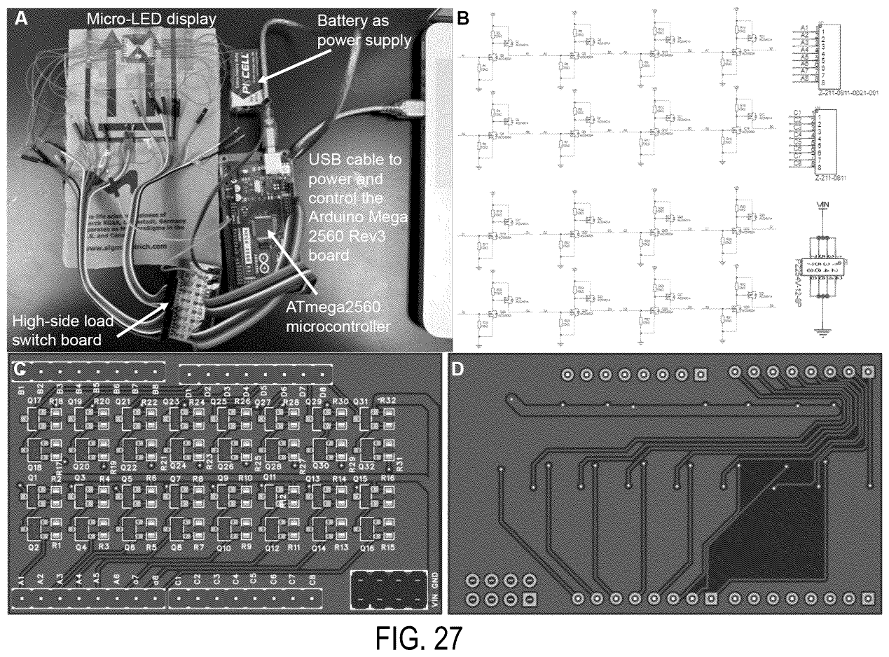

High-performance CuIn₅Se₈ transistor arrays can also be 3D monolithically integrated with GaN micro-LEDs to form an active matrix for high-resolution displays (FIG. 7A). FIG. 7B shows an 8×8 array, where the source electrode of the top-layer transistor is connected through a vertical via to the anode of a 10×10-˜m² micro-LED in each pixel (FIG. 7C). The CuIn₅Se₈ transistor can deliver a high output current above 1.4 mA, which is sufficient to drive the micro-LED to a high current density with a scaled device footprint (FIG. 7D), achieving a pixel pitch of 50 μm, which corresponds to a high display resolution of 508 PPI. For a single pixel, the micro-LED began to turn on with the increase in the gate bias applied to the CuIn₅Se₈ transistor, up to a current density greater than 200 A cm⁻², after the applied V_{DD} went above ˜2.5 V, which is its diode turn-on voltage (FIG. 7E). The device could be switched rapidly between on and off states at 480 Hz (FIG. 7F). Each pixel was individually addressable using word lines connected to gate electrodes of CuIn₅Se₈ transistors along the column and bit lines connected to their drain electrodes along the row, with cathodes of all micro-LEDs grounded. Varying voltages applied on the word (gate) lines could modulate the brightness of micro-LEDs, which exhibited a 100% device yield (FIG. 7G). The uniformity was limited partially by the variation of the fabricated micro-LEDs (FIG. 26) and partially by the threshold voltage variability of the drive transistors (FIG. 15D). The matrix was connected to an external control board (FIG. 27), which drove the display of the alphabetic character “I,” using progressive scanning (FIG. 7H). These results verify that CuIn₅Se₈ thin films can be directly synthesized on GaN/silicon wafers to deliver a high performance comparable to polycrystalline silicon or MoS₂ but at a much lower thermal budget (less than 400° C.) using a solution-based process, which can achieve higher fabrication throughput with a lower cost and also avoid the concern of thermal degradation that is associated with multi-quantum wells and their interconnection with GaN micro-LEDs.

FIG. 5 depicts a 3D inverter that monolithically integrated CuIn₅Se₈ and carbon nanotube thin-film transistors. (A and B) Schematic (A) and cross-sectional sketch (B) of a 3D complementary inverter. V_{dd}, drive voltage; Vᵢₙ, input voltage; Vₒᵤₜ, output voltage; Gnd, ground voltage; S, source; D, drain. (C) AFM micrographs of the solution-deposited carbon nanotube random networks on the top surface at low (scale bar, 5 μm) and high (inset, scale bar, 2 μm) magnifications. (D and E) transfer characteristics (dD) of the top-tier nanotube transistor with W=150 μm and L_{ch}=5 μm, plotted in both linear (left axis, lines) and logarithmic (right axis, dots) scales, with the applied V_{dS} increasing from 0.1 V (black) to 0.4 V (red), 0.7 V (blue), and 1 V (green), and the corresponding current-voltage characteristics [(E); the V_{GS} increased from −4 to 0 V from top to bottom with a step of 0.5 V]. (F) current-voltage characteristics of the bottom-tier CuIn₅Se₈ transistors (W=100 μm and L_{ch}=5 μm), measured after completing the circuit with descending V_{GS} from 5 to 0 V at a step of 1 V from top to bottom. (G) Optical micrograph of a completed 3D inverter. (H) direct (black solid line) and mirrored (blue dashed line) voltage transfer characteristics (left axis, black) and the associated voltage gain (right axis, red). The orange rectangles indicate static noise margins determined according to the maximum equal criterion principle. Inset: circuit diagram. (I to L) Optical micrographs [(I) and (K)] and output-input characteristics [(J) and (L)] of a NOR gate [(I) and (J)] and a NAND gate [(K) and (L)]. Insets: circuit diagrams. Scale bars, 100 μm.

FIG. 6 depicts a high-speed ring oscillator. (A and B) Optical micrograph [(A); scale bar, 100 μm] and circuit diagram (B) of a 3D five-stage ring oscillator with buffer. (C) Output waveforms of the ring oscillator operating with a frequency of 1.33 Mhz under a V_{dd} of 6 V. (D) comparison of stage delay among ring oscillators built on solution-processable semiconductors.

FIG. 7 depicts a monolithic micro-LED display driven by CuIn₅Se₈ transistors. (A and B) Schematic (A) and optical micrograph (B) of the active matrix micro-LED display. Scale bar, 100 μm. (C) Magnified view of a single pixel composed of a 10×10 μm² micro-LED and a 35 (W)×4 (L_{ch}) μm² CuIn₅Se₈ thin-film transistor. Scale bar, 10 μm. (D) current-voltage characteristics of the CuIn₅Se₈ drive transistor (blue lines, left axis) and the GaN micro-LED (red dots, right axis) in a pixel. (E) current-voltage characteristics of a pixel with the gate bias applied to the CuIn₅Se₈ drive transistor ranging from 20 to 0 V in a step of 4 V from top to bottom. Inset: pixel circuit diagram of a one-transistor-one-diode scheme. (F) Modulation of the diode current under 480-Hz voltage pulses oscillating between 0 and 10 V applied to the gate of the CuIn₅Se₈ drive transistor. The applied V_{dd} was 5 V. (G) Micro-LED brightness controlled by applying different bias along the word (gate) lines. Scale bar, 100 μm. (H) Optical image of the display showing the letter I. Scale bar, 100 μm.

### Materials and Methods

Deposition of Cu—In—Se Thin Films from Hydrazinium Salt Precursors Dissolved in Hydrazine

A Cu₂S precursor solution was prepared by mixing 1 mmol (63.5 mg) of Cu powders (Alfa Aesar, 99.999%) and 2 mmol (64.1 mg) of sulfur flakes (Sigma-Aldrich, 99.998%) with 10 ml of anhydrous hydrazine (Sigma-Aldrich, 98%) to result in a clear yellow solution after 1 week of stirring. An In₂Se₃ precursor solution was formed by mixing 2.5 mmol (1.166 g) of In₂Se₃ crystals (Alfa Aesar, 99.99%) and 2.5 mmol (0.197 g) of Se pellets (Sigma-Aldrich, 99.999%) with 10 ml of hydrazine, yielding a clear colorless solution after 1 week of stirring. Because hydrazine is toxic, each component was prepared in a nitrogen-filled glove box with both water and oxygen maintained below the 1 ppm (part per million) level. For manufacturing, hydrazine can be potentially replaced with other less toxic solvents such as a mixture of diamine and dithiol. The solution for spin casting was prepared by mixing the appropriate quantities of each component solution to yield a targeted elemental stoichiometry in a single homogeneous solution. This mixed solution was stirred for another week prior to deposition with an added additional amount of hydrazine to set the indium concentration to 0.1 M.

The substrates were silicon wafers with 90-nm thermal oxide or glass slides (for device fabrication), amorphous quartz disks [for ultraviolet-visible (UV-vis) characterization], or bare silicon wafers (for RBS analysis). HfO₂ (40 nm), which functioned as a barrier blocking the diffusion of impurity ions from the substrate (especially glass), was grown on top by atomic layer deposition (ALD) (Savannah 100) at 150° C. using tetrakis(dimethylamido)hafnium and water as precursors. After cleaning the substrate surface with oxygen plasma, spin coating was performed inside a nitrogen-filled glove box by flooding the substrate surface with the appropriate solution passed through a 0.2-μm Teflon filter (Millipore) and then spinning the substrate at 4000 rpm for 60 s. The films were immediately dried and partially decomposed on a hot plate inside the glove box at 120° C. for 5 min with a quartz cover. After cooling down the substrate to room temperature, it was transferred to a tube furnace. Annealing at around 380° C. with argon [1000 standard cubic centimeters per minute (SCCM)] and hydrogen (100 SCCM) flow under a base pressure of 100 millitorr fully decomposed the precursors and crystallized the film formed by the above process. The substrate with the Cu—In—Se film deposited on top was retrieved from the tube furnace after cooling down to 60° C., which could then be processed and stored in air.

### TEM/STEM Characterizations

The cross-sectional samples were prepared using the Thermo Scios 2 DualBeam scanning electron microscopy/focused ion beam. The STEM was performed on an FEI Themis Z analytical TEM/STEM with a high-brightness Schottky field-emission electron source (X-FEG) in the STEM NanoProbe SA Zoom Diffraction Mode (probe corrected and operated at 300 kV). Images were collected using a high-angle annular dark-field STEM detector with beam convergence angle of 18 mrad and the camera length of 115 mm. The dwell time was 10 μs, and the frame time was 12.6 s in total. The corresponding EDS spectra were acquired over an area of 30×15 nm² through an integrated four-crystal EDS detection system (FEI Super-X). The dwell time was 10 μs, and the shaping time was 3 μs. The pixel size was 70 μm. The beam current was kept at around 250 pA. Diffraction analysis through the scanning electron nanodiffraction was based on the data collected with the FEI Ceta 16M 16-megapixel digital camera. A drift correction algorithm was applied to reduce the sample drift effect. The diffraction pattern datasets were collected over sample areas of 100×20 nm² and the detector size of 1.7 pixels.

### Fabrication of Thin-Film Transistors

After depositing Cu—In—Se thin films following the spin casting process from their solution precursors as described above, transistor source-drain electrodes were first patterned into photoresist (AZ 5214) by photolithography, followed by electron beam evaporation of 60-nm Cu/20-nm Au/1-nm Ti and lift-off in hot acetone. The 1-nm Ti was used as the seeding layer for the subsequent growth of ˜50-nm HfO₂ gate oxide/interlayer dielectric on top by ALD. Afterward, another photolithography was used to create the corresponding device gate patterns, which overlapped with the source-drain contacts by ˜5 μm on each side to accommodate possible alignment error. Electron beam evaporation deposited 1-nm Ti/80-nm Au as the gate-metal stack followed by lift-off in acetone. A final lithography step was performed to protect the active channel of each device. A subsequent CHF₃ and Ar mixed reactive ion etching (RIE) (Oxford Mixed ICP-RIE system) then removed the HfO₂ dielectric together with the underneath Cu—In—Se film in unprotected areas to isolate neighboring transistors and expose the probing pads for device source-drain contacts. The inductively coupled plasma (ICP) power was 300 W, the RIE power was 200 W, the flow rates of CHF₃ and Ar were 10 and 5 SCCM, respectively, and the chamber pressure was maintained at 5 millitorr during a processing time of 4.5 min. Removing the photoresist mask in acetone completed the transistor fabrication flow.

### Fabrication of 3D Monolithically Integrated Complementary Logic Circuits

Another layer of ˜30-nm HfO₂ was first deposited on top of the completed CuIn₅Se₈ transistors, which served as both the gate oxide for the top-layer, bottom-gated nanotube transistors, and the interlayer dielectric. Some of the source-drain and gate probing pads of the bottom-layer CuIn₅Se₈ transistors were then exposed in photoresist by photolithography, followed by etching of the HfO₂ in ICP-RIE. Afterward, high-density random networks of carbon nanotubes were deposited on top by a drop casting method, from a dispersion of high-purity (>99.9%) semiconducting nanotubes (IsoSol-S100, Nanointegris) with a concentration of ˜1 mg ml⁻¹. After deposition, the substrate was thoroughly washed with both toluene and isopropanol and then baked at 150° C. for 30 min in vacuum, which removed the surfactant wrapping nanotubes to improve the nanotube-nanotube and nanotube-metal contacts. Source-drain contacts to nanotubes, interconnect lines, and interlayer vias were then defined in a single step by photolithography and electron beam evaporation of a 0.2-nm Ti/40-nm Pd/40-nm Au metal stack with lift-off in acetone. Lastly, another photolithography and oxygen plasma etching step (Plasm-Therm, 100 W with an O₂ flow rate of 19 SCCM to keep a chamber pressure of 50 millitorr) defined the channel region of each nanotube thin-film transistor by removing carbon nanotubes in unprotected areas, which completed the circuit fabrication flow.

Fabrication of High-Resolution Micro-LED Displays Driven by CuIn₅Se₈ Transistors

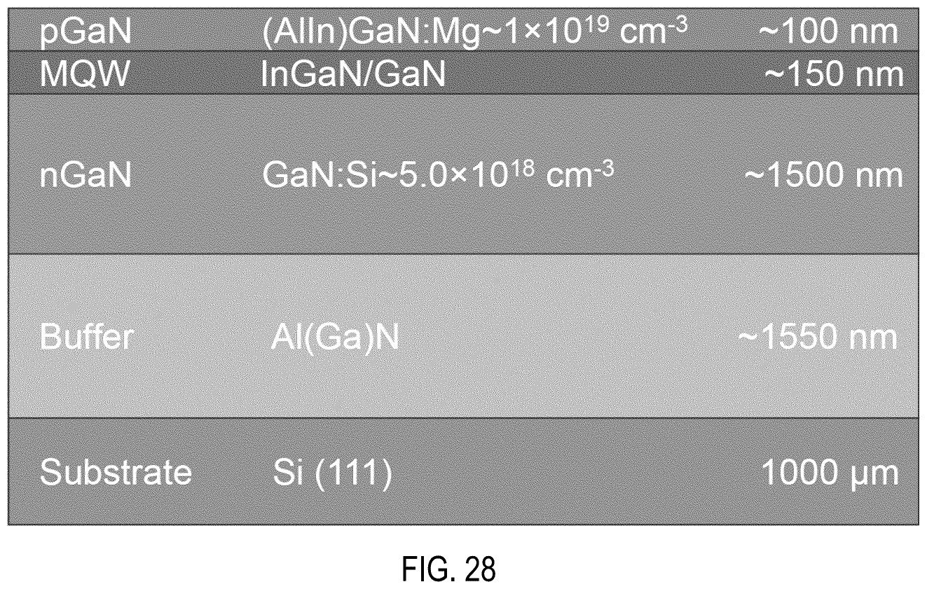

A GaN/Si (111) wafer (Enkris), with epitaxial layers of Mg-doped p-(AlIn)GaN (120 to 170 nm), InGaN/GaN multiple quantum wells (100 to 200 nm), silicon-doped n-GaN (1.4 to 1.6 μm), and Al(Ga)N buffer (1.5 to 1.7 μm) grown on silicon, served as the starting substrate (FIG. 28). Photoresist was patterned by lithography to first protect the p-region of each individual micro-LED, followed by an ICP-RIE mesa etch under a flow rate of 15 SCCM for BCl₃ for 2 min and then 20 SCCM for Cl₂ for another 2.5 min to expose the silicon-doped n-GaN layer. The ICP power and RIE power were kept at 100 and 300 W, respectively. Another photolithography step was then performed to expose regions corresponding to contact cathodes of micro-LEDs in photoresist, followed by electron beam evaporation of a multiple metal layer of 15-nm Ni/60-nm Al/60-nm Ni/50-nm Au and lift-off in hot acetone. Rapid thermal annealing at 860° C. for 30 s under nitrogen ambient conditions formed low-resistance, ohmic contact with the n-doped GaN:Si layer. Afterward, the wafer was soaked in a concentrated (˜28%) HCl aqueous solution for 5 min to remove the native oxide on the surface, and photoresist was spin cast on top immediately. The anode patterns of micro-LEDs were written into the photoresist by lithography, followed by electron beam evaporation of a semitransparent metal bilayer of 10-nm Ni/10-nm Au and lift-off in acetone. Annealing at 500° C. for 10 min in air formed low-resistance, ohmic contact to the p-doped (AlIn) GaN:Mg layer. Contact pads covering the top half of the anode (p-terminal) and the entirety of the cathode (n-terminal) were then defined by the fourth lithography level into the photoresist, followed by the electron beam evaporation of 10-nm Ti/200-nm Au/10-nm Ti and lift-off to form thick and opaque contact pads. The wafer was then blanketly passivated with 40-nm HfO₂ deposited by ALD. Open vias were subsequently defined by one additional lithography step into the photoresist on top of the thick contact pads to the anodes and cathodes, followed by etching of the 40-nm HfO₂ in ICP-RIE. After removing the photoresist, the wafer was soaked in a 6:1 buffered oxide etchant for 1 min to remove the titanium layer covering the top of contact pads along with various residues to afford a clean metal surface. The sixth lithography level simultaneously defined patterns corresponding to the contact pad of each anode and the interconnect lines connecting all cathodes of the micro-LEDs to a common ground electrode, all sitting on top of the HfO₂ barrier layer. Afterward, a thick metal multilayer of 10-nm Ti/200-nm Au/10-nm Ti was blanketly deposited by sputtering, which gave a continuous coverage over large surface height variations over the micro-LED mesas, followed by lift-off. The entire wafer was then covered with 60-nm HfO₂ deposited by ALD, which served as the interlayer dielectric separating the completed micro-LEDs from the CuIn₅Se₈ transistor arrays to be fabricated on top.

After completing the CuIn₅Se₈ transistors (W=35 μm and L_{ch}=4 μm) with their drain electrodes connected along the same row with bit lines and their gate electrodes connected along the same column with word lines, lithography steps were performed to expose the anode contact pads of the micro-LEDs and the source electrodes of the CuIn₅Se₈ transistors under the transistor gate oxide, again with the help of timed ICP-RIEs. These exposed electrodes in each pixel were connected via a thick metal multilayer of 1-nm Ti/200-nm Au/1-nm Ti as interlayer vias defined by lithography, sputtering deposition, and metal lift-off. Lastly, the entire substrate was passivated with 40-nm HfO₂ deposited by ALD to improve overall system reliability, followed by the last lithography step and ICP-RIE to expose probing pads for the word and bit lines as well as the common ground of the active matrix.

### Computational Method

DFT calculations were performed using the Vienna ab initio simulation package, using the projector augmented wave method. The energy cutoff for the plane-wave basis was set to 600 eV, and the energy convergence criterion was set to 10⁻⁶ eV. For structure relaxation, the PBEsol functional was used with a k-point grid of 12×12×6 for CuInSe₂ and CuIn₅Se₈ and 6×6×2 for In₂Se₃. For accurate electronic structure calculations, the HSEsol functional was used with a k-point grid of 2×2×1 for CuInSe₂ and CuIn₅Se₈ and 3×3×1 for In₂Se₃. Carrier mobilities at 300 K were calculated using AMSET to account for both phonon and ionized impurity scatterings. Inputs to AMSET were calculated from DFT, specifically the low-frequency and high-frequency dielectric constants and phonon frequencies. The calculations used a tighter energy convergence criterion of 10⁻⁸ eV. Phonon frequencies and the low-frequency dielectric constant were calculated using density functional perturbation theory with the PBEsol functional. The high-frequency dielectric constant was calculated with the HSEsol functional using the independent particle approximation and subsequently scissor shifted by the difference between the HSEsol and experimental bandgap.

### Instrumentation

AFM topography images were measured in tapping mode using an Asylum Research Cypher, with S-Tap300Al tapping tips from BudgetSensors. The film composition was determined by RBS using the NEC Pelletron accelerator equipped with RBS chamber. XPS spectra were obtained with a PHI 5600ci spectrometer equipped with a hemispherical electron analyzer and a monochromatic Al Kα (1486.6 eV) radiation source. The pass energy of the analyzer was 55 eV. Electrical characterizations of individual transistors, capacitors, and integrated circuits was performed using a manual probe station (Lake Shore Cryotronics CRX-6.5 K) in a controlled temperature and environment, with a semiconductor parameter analyzer (Keysight B1500A) equipped with an integrated high-resolution source measurement unit (Keysight B1517A), multifrequency capacitance measurement unit (Keysight B1520A), and waveform generator/fast measurement unit (Keysight B1530A). The ring oscillator output waveform was recorded using a Keysight DSOX1202A oscilloscope. Optical absorptions were recorded using a UV-vis absorbance spectrophotometer (Agilent Cary 5000). The AZ 5214E photoresist was patterned with a Heidelberg MLA150 aligner. The DFT simulations were performed on the Illinois Campus Cluster.

FIG. 8 depicts compositional uniformity of deposited CuIn₅Se₈ film. 146 points mapping of the normalized Cu (part A), In (part B), and Se (part C) atomic content variation of a CuIn₅Se₈ thin film deposited on a four-inch wafer substrate as measured by EDS. The standard deviation was less than 8%. Scale bar: 2 cm.

FIG. 9 depicts the thickness of deposited CuIn₅Se₈ film as measured by AFM. AFM image (part A, scale bar: 1 μm) and associated line-cut profile (part B) of a CuIn₅Se₈ thin film patterned to generate a step height.

FIG. 10 depicts transfer characteristics of transistors built on CuIn₅Se₈ thin films prepared with different conditions. (A) Impacts from different channel layer post annealing temperature (part A) and film thickness (part B, controlled by adjusting the precursor concentration from 0.01, to 0.02, and 0.04 mol·L⁻¹ with film thickness measured by AFM).

FIG. 11 depicts XPS spectra of Cu—In—Se films with varied stoichiometries deposited from solution. (A-C) High-resolution XPS spectra of the major elements of Cu (part A), In (part B), and Se (part C) in solution-deposited Cu—In—Se films of the stoichiometry of In₂Se₃ (black), CuIn₅Se₈ (red), CuIn₃Se₅ (blue), and Cu_{0.9}InSe₂ (green). (D-F) For each element of Cu (part D, black), In (part E, blue), and Se (part F, green) in Cu—In—Se films, as a semiquantitative method, their integrated XPS peak areas scaled proportionally with the target atomic concentrations. The red dashed line represents linear fit to the data.

FIG. 12 depicts a high-resolution STEM image of CuIn₅Se₈ thin films. White boxes highlight the representative grain boundary areas where there is an abrupt change in atomic plane orientations with dashed yellow lines as visual guide. Scale bar: 5 nm.

FIG. 13 depicts scanning electron nano-diffraction imaging visualizing the grain structure of Cu—In—Se films with varied stoichiometries deposited from solution. (A-D) Orientation maps (top frames, different color represents a different grain with a different orientation, identified from their corresponding different diffraction patterns shown in bottom frames) of deposited thin films of CuIn₅Se₈ (part A), CuIn₃Se₅ (part B), CuInSe₂ (part C), and In₂Se₃ (part D). Scale bars: 10 nm. (E-G) Radial intensities (red line) and probabilities (blue bar histogram) as a function of d-spacing obtained from the electron nano-diffraction patterns in comparison to the profiles (black lines) simulated from their lattice structures for CuIn₅Se₈ (part E), CuInSe₂ (part F), and In₂Se₃ (part G).

FIG. 14 depicts the temperature dependence of the hysteresis of CuIn₅Se₈ transistor. (A) Transfer characteristics of a CuIn₅Se₈ transistor for temperatures from 120 to 290 K. Arrows indicate the gate voltage sweep direction. (B) Hysteresis, defined as the shift of the V_{T} between two branches in the transfer curves with opposite sweep directions, as a function of temperature.

FIG. 15 depicts uniformity mapping of CuIn₅Se₈ transistors fabricated over a 2 cm by 2 cm substrate. Mapping of the effective mobility (part A), subthreshold swing (part B), on/off ratio (part C) and threshold voltage (part D) of a 16×12 array of fabricated CuIn₅Se₈ transistors. White squares correspond to devices that failed due to either lithography error (shorted source-drain electrodes) or defects in gate dielectrics (large gate leakage current).

FIG. 16 depicts batch-to-batch variation. (A-B) Transfer characteristics of CuIn₅Se₈ transistors (L_{ch}=5 μm and W=150 μm) fabricated in two different batches plotted in linear (part A) and logarithmic (part B) scales. (C) Comparison of the effective mobility of these transistors fabricated in two batches. The P value for a two-sample unequal variance t-test was 0.5, indicating that their difference was not statistically significant. Error bars represent standard deviation (s.d.).

FIG. 17 depicts contact resistance of CuIn₃Se₅ and In₂Se₃ transistors. Transfer characteristics of CuIn₃Se₅ (part A) and In₂Se₃ (part B) transistors with W of 150 μm and L_{ch} of 5 μm (black), 10 μm (red), 20 μm (blue), and 50 μm (green) in both logarithmic (left axis, dots) and linear scales (right axis, lines). Applied V_{D}S was 0.1 V. Width-normalized channel resistance as a function of L_{ch} at varied gate over drive (V_{ON}=V_{GS}−V_{T}) from 0.5 V to 3 V at a step of 0.5 V from top to bottom for CuIn₃Se₅ (part C) and In₂Se₃ (part D) transistors.

FIG. 18 depicts the dielectric constant of HfO₂. (A) An optical image of an array of square-shaped capacitors with their side lengths (W) varied from 20 μm to 180 μm. Scale bar: 200 μm. (B) Measured capacitance-voltage characteristics of the capacitors shown in part A. (C) Capacitance (C)/W ratio as a function of W. The red dashed line represents a linear fit to the data (black dots).

FIG. 19 depicts characteristics of the CuIn₅Se₈ transistor exhibiting the maximum observed field-effective mobility. (A) Transfer characteristics in both logarithmic (left axis, dots) and linear scales (right axis, lines), with the applied V_{D}S increasing from 0.1 V (black) to 0.4 V (red), 0.7 V (blue), and 1 V (green). (B) Output characteristics measured with descending V_{GS} from 5 V to 0 V at a step of 1 V from top to bottom. (C) The effective mobility (μ_{eff}) extracted with V_{DS}=0. 1 V as a function of V_{GS} encompassing both forward and reverse sweeps.

FIG. 20 depicts transistors built on a more indium-rich Cu—In—Se semiconductor. (A) Collection of transfer characteristics of transistors with identical dimensions (W=150 μm, L_{ch}=5 μm) built on more indium-rich films with a nominal indium to copper ratio of 7. Applied VDS was 0.1 V. (B) Histograms illustrating the distribution and average of effective mobility of 42±7 cm²·V⁻¹s⁻¹.

FIG. 21 depicts channel width and length scaling characteristics of CuIn₅Se₈ transistors. (A-B) Collection of transfer curves of CuIn₅Se₈ transistors with identical width of 150 μm but L_{ch} varied from 5 μm (black) to 10 μm (red), 20 μm (blue), and 50 μm (magenta), plotted in linear (part A) and logarithmic (part B) scales. Applied V_{DS} was 0.1 V. (C-D) Collection of transfer curves of CuIn₅Se₈ transistors with identical widths of 100 μm but varied L_{ch}, plotted in linear (part C) and logarithmic (part D) scales. (E-F) Collection of transfer curves of CuIn₅Se₈ transistors with identical width of 50 μm but varied L_{ch}, plotted in linear (part E) and logarithmic (part F) scales. (G) Device onstate conductance (Rₒₙ⁻¹) extracted at V_{GS}=5 V as a function of W for L_{ch} varied from 5 μm (black) to 10 μm (red), 20 μm (blue), and 50 μm (magenta). Dashed lines represent linear fits to the data. Error bars represent s.d. (H) Device on-state resistance (Rₒₙ) as a function of L_{ch} for W varied from 150 μm (black) to 100 μm (red) and 50 μm (blue).

FIG. 22 depicts contact resistance of CuIn₅Se₈ semiconductor thin films. Collection of transfer curves (applied V_{D}S is 0.1 V) of CuIn₅Se₈ transistors with identical width of 150 μm but L_{ch} varied from 5 μm (black) to 10 μm (red), 20 μm (blue), and 50 μm (magenta) (left frames), and the change of the extracted width-normalized resistance as a function of L_{ch} under V_{OV} of 2 V (black), 1.5 V (red), 1 V (blue), and 0.5 V (green) (right frames, dashed lines represent linear fittings to the data). A-B, Al; C-D, Ti; E-F; Cr; and G-H, Au contact. I-J, Transfer curves of CuIn₅Se₈ transistors with identical width of 150 μm and L_{ch} of 5 μm but different contact metals of Al (black), Ti (red), Cr (blue), Cu (green), and Au (purple), plotted in logarithmic (part I) and linear (part J) scales. K-L, Width-normalized contact resistance (2R W) of different metal contacts to CuIn₅Se₈, plotted in logarithmic (part K) and linear (part L) scales. Metal work functions are labelled to illustrate that the contact resistance was mainly determined by interface chemistry rather than band alignment with the electron affinity of CuIn₅Se₈. Error bars represent s.d.

FIG. 23 depicts the stability of CuIn₅Se₈ transistors. (A) Evolution of transfer characteristics of one CuIn₅Se₈ transistor stored in air at 25° C. and 30-50% humidity for eight months, showing little change in device hysteresis. (B-C) The drift of device threshold voltage (part B) and on-state current (part C) as a function of time. (D-E) Transfer characteristics of a CuIn₅Se₈ transistor before (black) and after annealing in air at 200° C. (red) and 300° C. (blue) for 10 min, plotted in linear (part D) and logarithmic (part E) scales, respectively. (F) Transfer characteristics of one CuIn₅Se₈ transistor before (black) and after (blue) being stored in air at 35° C. and >90% humidity for 3 days. The modulations of I_{D} (lines) and transconductance gₘ (dots) by applied V_{GS} are shown as the left and right axis, respectively. (G) The same transfer curves as in part F plotted in logarithmic scale.

FIG. 24 depicts stability tests of CuIn₅Se₈ transistors. (A) PBTS. (B) PBIS. (C) NBTS. (D) NBIS. Thermal stress was 60° C. and illumination was introduced as bright coaxial white light from a LED light source.

FIG. 25 depicts bias-stress stability tests of In₂Se₃ transistors. (A-B) PBS (part A) and NBS (part B) data of In₂Se₃ transistors measured during two-hour bias-stress conditions with a positive or negative gate bias of V_{G,bias}=±5 V and drain bias of V_{D,bias}=0 V. (C) Corresponding ΔV_{T} as a function of stress time for PBS (black) and NBS (green) tests.

FIG. 26 depicts spatial uniformity of fabricated micro-LEDs. (A) Optical image of a micro-LED array without drive transistors. Scale bar: 100 μm. (B) Collection of the diode current-voltage characteristics of all 64 micro-LEDs. (C) Mapping of the diode current density (j_{Diode}).

FIG. 27 depicts a system addressing the active-matrix micro-LED display. (A) Optical image of the experimental setup. (B-D) Schematic diagram (part B) of the 16-channel high-side load switches and the design layout for the top (part C) and the bottom (part D) layers of the associated printed circuit board.

FIG. 28 depicts the GaN epitaxial structure for the micro-LEDs describe herein. 3.3 μm thick epitaxial structure on 8-inch silicon (111) wafer for the fabrication of blue LEDs.

### III. EXAMPLE METHODS

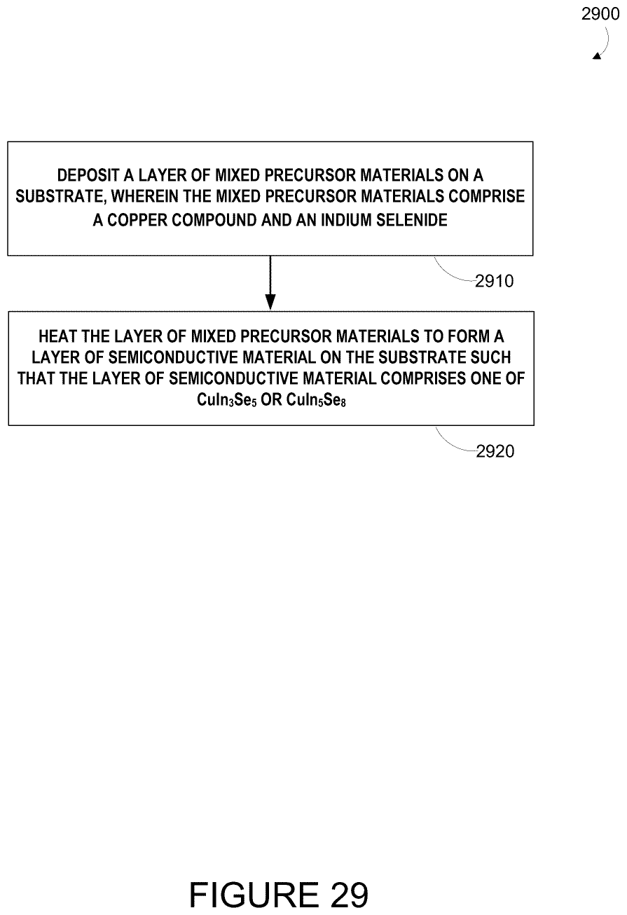

FIG. 29 is a flowchart of an example method 2900 for generating a semiconductor device or other article that includes a semiconductor material that includes CuIn₃Se₅ and/or CuIn₅Se₈, e.g., an article that includes one or more transistors whose channels include a CuIn₃Se₅ and/or CuIn₅Se₈ semiconductor material. The method 2900 includes depositing a layer of mixed precursor materials on a substrate, wherein the mixed precursor materials comprise a copper compound and an indium selenide (2910). The method 2900 also includes heating the layer of mixed precursor materials to form a layer of semiconductive material on the substrate such that the layer of semiconductive material comprises one of CuIn₃Se₅ or CuIn₅Se₈ (2920). The method 2900 could include additional or alternative features.

### IV. CONCLUSION

The above detailed description describes various features and functions of the disclosed systems, devices, and methods with reference to the accompanying figures. In the figures, similar symbols typically identify similar components, unless context indicates otherwise. The illustrative embodiments described in the detailed description, figures, and claims are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

With respect to any or all of the message flow diagrams, scenarios, and flowcharts in the figures and as discussed herein, each step, block and/or communication may represent a processing of information and/or a transmission of information in accordance with example embodiments. Alternative embodiments are included within the scope of these example embodiments. In these alternative embodiments, for example, functions described as steps, blocks, transmissions, communications, requests, responses, and/or messages may be executed out of order from that shown or discussed, including in substantially concurrent or in reverse order, depending on the functionality involved. Further, more or fewer steps, blocks and/or functions may be used with any of the message flow diagrams, scenarios, and flow charts discussed herein, and these message flow diagrams, scenarios, and flow charts may be combined with one another, in part or in whole.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims.

1. An electronic system comprising:
a transistor, wherein the transistor comprises:
a channel, wherein the channel comprises a layer of semiconductive material comprises one of CuIn₃Se₅ or CuIn₅Se₈.

2. The electronic system of claim 1, wherein the layer of semiconductive material comprises CuIn₃Se₅.

3. (canceled)

4. The electronic system of claim 1, wherein the layer of semiconductive material comprises CuIn₅Se₈.

5. (canceled)

6. The electronic system of claim 1, further comprising a contact composed of at least one of chrome or copper, wherein the contact is in contact with the layer of semiconductive material, and wherein the transistor is configured such that the contact operates as at least one of a source or a drain of the transistor.

7-12. (canceled)

13. The electronic system of claim 1, wherein the transistor additionally comprises a gate, the transistor is configured as a FET with the layer of semiconductive material acting as a channel of the transistor whose conductivity is controllable by controlling a charge on the gate, wherein the electronic system further comprises a second transistor that is configured as a second FET with a second layer of semiconductive material acting as a channel of the second transistor whose conductivity is controllable by controlling the charge on the gate, and wherein the channel of the second transistor comprises one of p-doped carbon nanotubes, a layer of n-doped CuIn₃Se₅, or a layer of n-doped CuIn₅Se₈.

14. (canceled)

15. A semiconductive material comprising one of CuIn₃Se₅ or CuIn₅Se₈.

16. The semiconductive material of claim 15, wherein the semiconductive material comprises CuIn₃Se₅.

17. The semiconductive material of claim 16, wherein an atomic ratio between Cu and In in the semiconductive material is between 2.4 and 3.6.

18. The semiconductive material of claim 15, wherein the semiconductive material comprises CuIn₅Se₈.

19. The semiconductive material of claim 18, wherein an atomic ratio between Cu and In in the semiconductive material is between 4 and 6.

20. The semiconductive material of claim 15, wherein the semiconductive material exhibits an electron mobility greater than 20 cm²/V/s.

21. A method comprising:
depositing a layer of mixed precursor materials on a substrate, wherein the mixed precursor materials comprise a copper compound and an indium selenide; and
heating the layer of mixed precursor materials to form a layer of semiconductive material on the substrate such that the layer of semiconductive material comprises one of CuIn₃Se₅ or CuIn₅Se₈.

22. The method of claim 21, wherein heating the layer of mixed precursor materials to form the layer of semiconductive material comprises subjecting the layer of mixed precursor materials to a temperature of at least 350 degrees Celsius.

23. The method of claim 22, wherein the copper compound is Cu₂S, and wherein the indium selenide is In₂Se₃.

24. The method of claim 22, wherein depositing the layer of mixed precursor materials on a substrate comprises applying a solution to the substrate and then evaporating a solvent of the solution off the substrate, leaving the copper compound and indium selenide deposited as a layer on the substrate.

25. The method of claim 24, wherein the solution additionally comprises elementary selenium, such that the layer of mixed precursor materials comprises the copper compound, the indium selenide, and atomic selenium.

26-28. (canceled)

29. The method of claim 22, wherein the layer of semiconductive material comprises CuIn₃Se₅.

30. The method of claim 29, wherein an atomic ratio between Cu and In in the layer of semiconductive material is between 2.4 and 3.6.

31. The method of claim 22, wherein the layer of semiconductive material comprises CuIn₅Se₈.

32. The method of claim 31, wherein an atomic ratio between Cu and In in the layer of semiconductive material is between 4 and 6.

33-38. (canceled)
